(19) United States
(12) Patent Application Publication
(10) Pub. No.: US 2026/0059921 A1
(43) Pub. Date: Feb. 26, 2026

(54) DISPLAY DEVICE AND ELECTRONIC DEVICE INCLUDING DISPLAY DEVICE

(71) Applicant: Samsung Display Co., LTD., Yongin-si (KR)

(72) Inventors: Sang Hyung LIM, Yongin-si (KR); Soo Chul KIM, Yongin-si (KR); So Young LEE, Yongin-si (KR); Won Ho LEE, Yongin-si (KR)

(21) Appl. No.: 19/221,884

(22) Filed: May 29, 2025

(30) Foreign Application Priority Data
Aug. 23, 2024 (KR) 10-2024-0113851

(51) Int. Cl. H10H 29/855; H01L 25/075

(52) U.S. Cl. CPC H10H 29/855; H01L 25/0753

(57) ABSTRACT

A display device includes a pixel circuit layer including a pixel circuit, a first light emitting element layer disposed on the pixel circuit layer, a second light emitting element layer disposed on the first light emitting element layer, a third light emitting element layer disposed on the second light emitting element layer, a first lens layer disposed between the first light emitting element layer and the second light emitting element layer, the first lens layer including a lens overlapping with the first light emitting element, a second lens layer disposed between the second light emitting element layer and the third light emitting element layer, the second lens layer including a lens overlapping with the second light emitting element and a third lens layer disposed on the third light emitting element layer, the third lens layer including lenses respectively overlapping with the first to third light emitting elements.

This application claims priority to Korean Patent Application No. 10-2024-0113851, filed on Aug. 23, 2024, and all the benefits accruing therefrom under 35 U.S.C. § 119, the content of which in its entirety is herein incorporated by reference.

### BACKGROUND

### 1. Technical Field

The invention generally relates to a display device, and more particularly to a display device and an electronic device including the display device.

### 2. Related Art

Recently, as interest in information displays is increased, research and development of display devices have been continuously conducted.

### SUMMARY

An embodiment provides a display device having improved light emission efficiency.

In accordance with an aspect, there is provided a display device including a pixel circuit layer including a pixel circuit, a first light emitting element layer disposed on the pixel circuit layer, the first light emitting element layer including a first light emitting element generating light of a first color, a second light emitting element layer disposed on the first light emitting element layer, the second light emitting element layer including a second light emitting element when generates light of a second color different from the first color and is spaced apart from the first light emitting element on a plane, a third light emitting element layer disposed on the second light emitting element layer, the third light emitting element layer including a third light emitting element which generates light of a third color different from the first color and the second color and is spaced apart from the first light emitting element and the second light emitting element on a plane, a first lens layer disposed between the first light emitting element layer and the second light emitting element layer, the first lens layer including a lens overlapping with the first light emitting element, a second lens layer disposed between the second light emitting element layer and the third light emitting element layer, the second lens layer including a lens overlapping with the second light emitting element and a third lens layer disposed on the third light emitting element layer, the third lens layer including lenses respectively overlapping with the first to third light emitting elements.

In an embodiment, at least some of the lenses included in the first to third lens layers may have a shape different from a shape of the others of the lenses included in the first to third lens layers.

In an embodiment, at least some of the lenses included in the first to third lens layers may have a curvature different from a curvature of the others of the lenses included in the first to third lens layers.

In an embodiment, a shape of a spherical surface of each of at least some of the lenses included in the first to third lens layers may be different from a shape of a spherical surface of each of the others of the lenses included in the first to third lens layers.

In an embodiment, at least some of the lenses included in the first to third lens layers may have the same shape of a spherical surface as the others of the lenses included in the first to third lens layers, and have a height different from a height of the others of the lenses included in the first to third lens layers.

In an embodiment, the first light emitting element layer may include a (1-1)th light emitting element and a (1-2)th light emitting element, which are spaced apart from the second light emitting element and the third light emitting element on a plane.

In an embodiment, the first lens layer may include first lenses respectively overlapping with the (1-1)th light emitting element and the (1-2)th light emitting element.

In an embodiment, the second lens layer may further include: a (2-1)th lens overlapping with the second light emitting element and (2-2)th lenses respectively overlapping with the (1-1)th light emitting element and the (1-2)th light emitting element.

In an embodiment, one or more lenses included in the first lens layer may have the same shape. One or more lenses included in the second lens layer may have the same shape. One or more lenses included in the third lens layer may have the same shape.

In an embodiment, the lenses included in the first lens layer may have a shape different from a shape of the lenses included in each of the second lens layer and the third lens layer. The lenses included in the second lens layer may have a shape different from a shape of the lenses included in the third lens layer.

In an embodiment, some of the lenses included in the second lens layer may have a shape different from a shape the others of the lenses included in the second lens layer. Some of the lenses included in the third lens layer may have a shape different from a shape of the others of the lenses included in the third lens layer.

In an embodiment, lenses overlapping with each other on a plane among the lenses included in the first to third lens layers may have the same shape.

In an embodiment, the first lens layer may include first sub-lenses overlapping with each of the (1-1)th light emitting element and the (1-2)th light emitting element.

In an embodiment, the second lens layer may include (2-1)th sub-lenses overlapping with the second light emitting element and (2-2)th sub-lenses overlapping with each of the (1-1)th light emitting element and the (1-2)th light emitting element.

In an embodiment, at least some of the lenses included in the first to third lens layers may have a shape convex toward the pixel circuit layer, and the others of the lenses included in the first to third lens layers may have a shape convex toward a direction opposite to the pixel circuit layer.

In an embodiment, each of the first to third light emitting element layers may further include an insulating layer. A refractive index of a material constituting each of the lenses having the shape convex toward the pixel circuit layer may be lower than a refractive index of a material constituting the insulating layer.

In an embodiment, each of the first to third light emitting element layers may further include conductive patterns surrounding the first to third light emitting elements without overlapping with the first to third light emitting elements on a plane.

In an embodiment, the first lens layer and the second lens layer may include the same material. The first and second lens layers and the third lens layer may have different materials.

In an embodiment, the first lens layer and the second lens layer may include an inorganic material, and the third lens layer may include an organic material.

In an embodiment, the display device may further include an overcoat layer disposed on the third lens layer, the overcoat layer covering the lenses included in the third lens layer.

In an embodiment, an electronic device may include a processor to provide input image data and a display device to display an image based on the input image data, wherein the display device comprises a pixel circuit layer including a pixel circuit, a first light emitting element layer disposed on the pixel circuit layer, the first light emitting element layer including a first light emitting element generating light of a first color, a second light emitting element layer disposed on the first light emitting element layer, the second light emitting element layer including a second light emitting element when generates light of a second color different from the first color and is spaced apart from the first light emitting element on a plane, a third light emitting element layer disposed on the second light emitting element layer, the third light emitting element layer including a third light emitting element which generates light of a third color different from the first color and the second color and is spaced apart from the first light emitting element and the second light emitting element on a plane, a first lens layer disposed between the first light emitting element layer and the second light emitting element layer, the first lens layer including a lens overlapping with the first light emitting element, a second lens layer disposed between the second light emitting element layer and the third light emitting element layer, the second lens layer including a lens overlapping with the second light emitting element and a third lens layer disposed on the third light emitting element layer, the third lens layer including lenses respectively overlapping with the first to third light emitting elements.

### BRIEF DESCRIPTION OF THE DRAWINGS

Example embodiments will now be described more fully hereinafter with reference to the accompanying drawings, however, the invention may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being disposed “between” two elements, it can be the only element between the two elements, or one or more intervening elements may also be present. Like reference numerals refer to like elements throughout.

FIG. 1 is a schematic block diagram illustrating a display device, according to an embodiment.

FIG. 2 is a schematic block diagram illustrating any one of sub-pixels shown in FIG. 1, according to an embodiment.

FIG. 3 is a plan view illustrating a display panel shown in FIG. 1, according to an embodiment.

FIG. 4 is a sectional view illustrating the display panel shown in FIG. 3, according to an embodiment.

FIG. 5 is a sectional view illustrating the display panel shown in FIG. 3, according to another embodiment.

FIG. 6 is an enlarged plan view illustrating a portion of a display area of the display panel shown in FIG. 3, according to an embodiment.

FIG. 7 is a sectional view taken along line I-I′ shown in FIG. 6, according to an embodiment.

FIG. 8 is an enlarged sectional view illustrating a first light emitting element shown in FIG. 7, according to an embodiment.

FIG. 9 is a sectional view illustrating other embodiments of FIG. 7, according to an embodiment.

FIG. 10 is a sectional view illustrating other embodiments of FIG. 7, according to an embodiment.

FIG. 11 is a sectional view illustrating other embodiments of FIG. 7, according to an embodiment.

FIG. 12 is a sectional view illustrating other embodiments of FIG. 7, according to an embodiment.

FIG. 13 is a sectional view illustrating other embodiments of FIG. 7, according to an embodiment.

FIG. 14 is a sectional view illustrating other embodiments of FIG. 7, according to an embodiment.

FIG. 15 is a sectional view illustrating other embodiments of FIG. 7, according to an embodiment.

FIG. 16 is a sectional view illustrating other embodiments of FIG. 7, according to an embodiment.

FIG. 17 is a sectional view illustrating other embodiments of FIG. 7, according to an embodiment.

FIG. 18 is a block diagram illustrating an electronic device including a display device, in accordance with an embodiment.

FIG. 19 is a graphical image illustrating an example where the electronic device of FIG. 18 is a smartphone, in accordance with an embodiment.

FIG. 20 is a graphical image illustrating an example where the electronic device of FIG. 18 is a tablet computer, in accordance with an embodiment.

### DETAILED DESCRIPTION

Hereinafter, embodiments of the invention are described in more detail with reference to the accompanying drawings. In the description below, only a necessary part to understand an operation according to the invention is described and the descriptions of other parts are omitted in order not to unnecessarily obscure subject matters of the invention. In addition, the invention is not limited to exemplary embodiments described herein, but may be embodied in various different forms. Rather, exemplary embodiments described herein are provided to thoroughly and completely describe the invention and to sufficiently transfer the ideas of the invention to a person of ordinary skill in the art.

Like numbers refer to like elements throughout. In the drawings, the thickness of certain lines, layers, components, elements or features may be exaggerated for clarity. It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Hereinafter, exemplary embodiments of the invention and items required for those skilled in the art to easily understand the content of the present disclosure will be described in detail with reference to the accompanying drawings. In the following description, singular forms in the invention are intended to include the plural forms as well, unless the context clearly indicates otherwise.

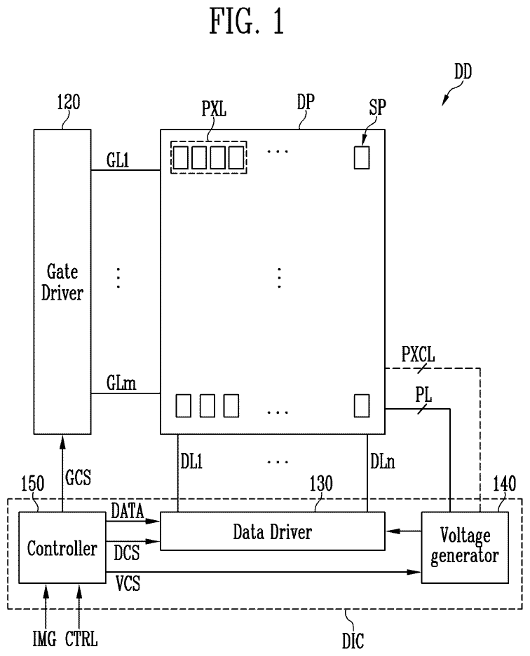

FIG. 1 is a block diagram illustrating an embodiment of a display device.

In an embodiment and referring to FIG. 1, the display device DD may include a display panel DP, a gate driver 120, a data driver 130, a voltage generator 140, and a controller 150.

In an embodiment, the display panel DP may include sub-pixels SP. The sub-pixels SP may be connected to the gate driver 120 through first to mth gate lines GL1 to GLm, respectively. The sub-pixels SP may be connected to the data driver 130 through first to nth data lines DL1 to DLn, respectively.

In an embodiment, the sub-pixels SP may generate lights of two or more colors. For example, each of the sub-pixels SP may generate lights of red, green, blue, cyan, magenta, yellow, white, and the like.

In an embodiment, two or more sub-pixels among the sub-pixels SP may constitute a pixel PXL. For example, the pixel PXL may include four sub-pixels as shown in FIG. 1. As such, the pixel PXL may emit lights of various colors with various luminance according to a combination of lights emitted from the sub-pixels included therein.

In an embodiment, the gate driver 120 may be connected to the sub-pixels SP arranged in a row direction through the gate lines GL1 to GLm. The gate driver 120 may output gate signals to the gate lines GL1 to GLm in response to a gate control signal GCS. In an embodiment, the gate control signal GCS may include a start signal indicating a start of each frame, a horizontal synchronization signal, and the like.

In an embodiment, the gate driver 120 may be disposed at one side of the display panel DP. However, the invention is not limited thereto. For example, the gate driver 120 may be divided into two or more drivers which are physically and/or logically divided, and these drivers may be disposed at one side of the display panel DP and an opposite side of the display panel DP, which is opposite to the one side. As such, in some embodiments, the gate driver 120 may be disposed in various forms at the periphery of the display panel DP.

In an embodiment, the data driver 130 may be connected to the sub-pixels SP arranged in a column direction through the data lines DL1 to DLn. The data driver 130 may receive image data and a data control signal DCS from the controller 150. The data driver 130 may operate in response to the data control signal DCS. In an embodiment, the data control signal DCS may include a source start pulse, a source shift clock, a source output enable signal, and the like.

In an embodiment, the data driver 130 may receive voltages from the voltage generator 140. The data driver 130 may apply data signals having grayscale voltages corresponding to the image data DATA to the data lines DL1 to DLn by using the received voltages. When a gate signal is applied to each of the gate lines GL1 to GLm, data signals corresponding to the image data DATA may be applied to the data lines DL1 to DLm. Accordingly, corresponding sub-pixels SP may generate light corresponding to the data signals. Accordingly, an image may be displayed on the display panel DP.

In an embodiment, the gate driver 120 and the data driver 130 may include complementary metal-oxide semiconductor (CMOS) circuit elements.

In an embodiment, the voltage generator 140 may operate in response to a voltage control signal VCS from the controller 150. The voltage generator 140 may be configured to generate a plurality of voltages and provide the generated voltages to components of the display device DD. The voltage generator 140 may generate a plurality of voltages by receiving an input voltage from an outside of the display device DD and regulating the received voltage.

In an embodiment, the voltage generator 140 may generate a first power voltage and a second power voltage. The generated first and second power voltages may be provided to the sub-pixels SP through power lines PL. In another embodiment, at least one of the first and second power voltages may be provided from the outside of the display device DD.

In an embodiment, the voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined reference voltage may be applied to the data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In an embodiment, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, the invention is not limited thereto. For example, the pixel control lines PXCL may be connected between the gate driver 120 and the display panel DP. The pixel control signals may be transferred to the sub-pixels SP from the gate driver 120 through the pixel control lines PXCL.

In an embodiment, the controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

In an embodiment, the controller 150 may convert the input image data IMG to be suitable for the display device DD or the display panel DP, thereby outputting the image data DATA. In an embodiment, the controller 150 may align the input image data IMG to be suitable for the sub-pixels SP in units of rows, thereby outputting the image data DATA.

In an embodiment, two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In another embodiment, at least one of the data driver 130, the voltage generator 140, and the controller 150 may be provided as a component distinguished from the driver integrated circuit DIC.

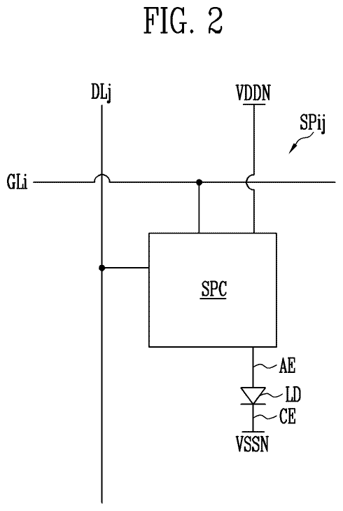

FIG. 2 is a block diagram illustrating an embodiment of any one of the sub-pixels shown in FIG. 1. In FIG. 2, a sub-pixel SPij arranged on an ith row (wherein i is an integer greater than or equal to 1 and smaller than or equal to m) and a jth column (where j is an integer greater than or equal to 1 and smaller than or equal to n) among the sub-pixels SP shown in FIG. 1 is exemplarily illustrated.

In an embodiment and referring to FIG. 2, the sub-pixel SPij may include a sub-pixel circuit SPC and a light emitting element LD.

In an embodiment, the light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

In an embodiment, the light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

In an embodiment, the sub-pixel circuit SPC may be connected to an ith gate line GLi among the gate lines GL1 to GLm shown in FIG. 1 and a jth data line DLj among the data lines DL1 to DLn shown in FIG. 1. In response to a gate signal received through the ith gate line GLi, the sub-pixel circuit SPC may control the light emitting element LD to emit light according to a data signal received through the jth data line DLj. In an embodiment, the sub-pixel circuit SPC may be further connected to the pixel control lines PXCL shown in FIG. 1. The sub-pixel circuit SPC may control the light emitting element LD in further response to control signals received through the pixel control lines PXCL.

In an embodiment, for these operations, the sub-pixel circuit SPC may include circuit elements, e.g., transistors and one or more capacitors.

In an embodiment, the transistors of the sub-pixel circuit SPC may include P-type transistors and/or N-type transistors. In an embodiment, the transistors of the sub-pixel circuit SPC may include a Metal Oxide Silicon Field Effect Transistor (MOSFET). In an embodiment, the transistors of the sub-pixel circuit SPC may include an amorphous silicon semiconductor, a monocrystalline silicon semiconductor, polycrystalline silicon semiconductor, an oxide semiconductor, and the like.

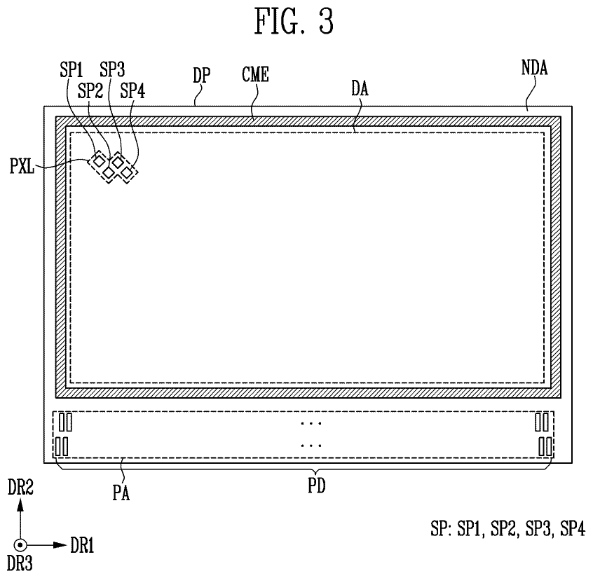

FIG. 3 is a plan view illustrating an embodiment of a display panel shown in FIG. 1.

In an embodiment and referring to FIG. 3, a display panel DP may include a display area DA, a non-display area NDA, and a pad area PA. The display panel DP may display an image through the display area DA. The pad area PA may be spaced apart from the display area DA in a second direction DR2. The non-display area NDA may be disposed at the periphery of the display area DA.

In an embodiment, the display panel DP may include a plurality of sub-pixels SP in the display area DA. The sub-pixels SP may be arranged in a first direction DR1 and the second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

In an embodiment, two or more sub-pixels among the plurality of sub-pixels SP may constitute one pixel PXL. In FIG. 3, it is illustrated that the pixel PXL includes four sub-pixels SP1 to SP4. However, the invention is not limited thereto. For example, the pixel PXL may include two or three sub-pixels. Hereinafter, for convenience of description, it is assumed that the pixel PXL includes first to fourth sub-pixels SP1 to SP4.

In an embodiment, each of the sub-pixels SP1 to SP4 may generate light of one of various colors such as red, green, blue, cyan, magenta, and yellow. Hereinafter, for clear and simple description, it is assumed that the first sub-pixel SP1 is configured to generate light of a red color, each of the second sub-pixel SP2 and the fourth sub-pixel SP4 is configured to generate light of a green color, and the third sub-pixel SP3 is configured to generate light of a blue color.

In an embodiment, each of the sub-pixels SP1 to SP4 may include at least one light emitting element configured to generate light. In an embodiment, light emitting elements of the sub-pixels SP1 to SP4 may generate light of the same color. For example, the light emitting elements of the sub-pixels SP1 to SP4 may generate light of a blue color. In another embodiment, the light emitting elements of the sub-pixels SP1 to SP4 may generate lights of different colors. For example, the light emitting elements of the sub-pixels SP1 to SP4 may generate lights of a red color, a green color, a blue color, and a green color, respectively.

In an embodiment, self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

In an embodiment, a component for controlling the sub-pixels SP and transferring a signal from pads PD may be disposed in the non-display area NDA. Signal lines which are included in the power lines PL shown in FIG. 1 and which are respectively connected to a common electrode CME which supplies the second power voltage VSSN shown in FIG. 2, the gate lines GL1 to GLm, and the data lines DL1 to DLn may be disposed in the non-display area NDA.

In an embodiment, the common electrode CME may receive the second power voltage VSSN transferred from some of the pads PD to supply the second power voltage VSSN toward an N-type semiconductor layer of the light emitting element, and other some of the pads except the pads PD transferring the second power voltage VSSN may supply the first power voltage VDDN toward a P-type semiconductor layer of the light emitting element. The light emitting element may emit light due to a voltage difference between the first power voltage VDDN and the second power voltage VSSN.

In an embodiment, at least one of the gate driver 120, the data driver 130, the voltage generator 140, and the controller 150, which are shown in FIG. 1, may be disposed in the non-display area NDA of the display panel DP. In an embodiment, the gate driver 120 may be disposed in the non-display area NDA. The data driver 150, the voltage generator 140, and the controller 150 may be implemented into the driver integrated circuit DIC shown in FIG. 1, which is distinguished from the display panel DP, and the driver integrated circuit DIC may be connected to lines disposed in the non-display area NDA through the pads PD. In another embodiment, the gate driver 120, the data driver 130, the voltage generator 140, and the controller 150 may be implemented into one integrated circuit distinguished from the display panel DP.

In an embodiment, the pads respectively connected to the lines (e.g., the common electrode CME and the signal lines) disposed in the non-display area NDA may be disposed in the pad area PA. The pads PD may be connected to the driver integrated circuit DIC.

In an embodiment, the display area DA may have various shapes. The display area DA may have a closed-loop shape including linear sides and/or curved sides. For example, the display area DA may have shapes such as a polygon, a circle, a semicircle, and an ellipse.

In an embodiment, the display panel DP may have a flat display surface. In another embodiment, the display panel DP may at least partially have a round display surface. In an embodiment, the display panel DP may be bendable, foldable or rollable. The display panel DP and/or a substrate of the display panel DP may include materials having flexibility.

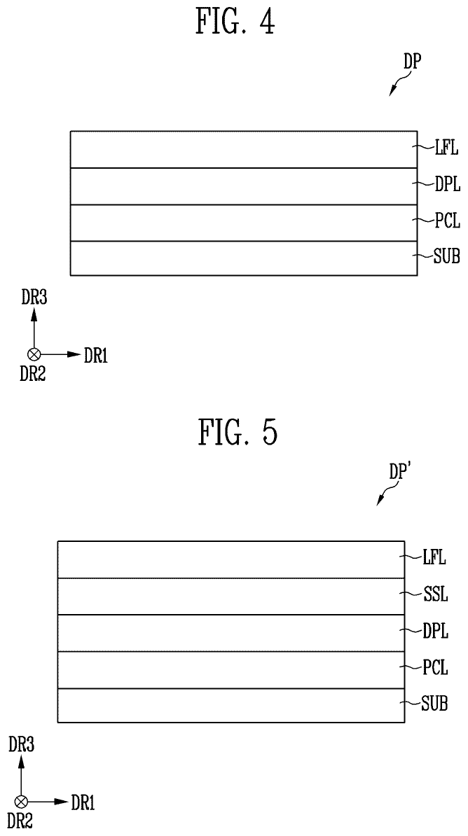

FIG. 4 is a sectional view illustrating an embodiment of the display panel shown in FIG. 3.

In an embodiment and referring to FIG. 4, a display panel DP may include a substrate SUB, and a pixel circuit layer PCL, a display element layer DPL, and a light functional layer LFL, which are sequentially stacked in a third direction DR3 intersecting the first and second directions DR1 and DR2, respectively, on the substrate SUB.

In an embodiment, the substrate SUB may be made of an insulative material such as glass or resin. For example, the substrate SUB may include a glass substrate. In another embodiment, the substrate SUB may include polyimide (PI) substrate. In still another embodiment, the substrate SUB may include a silicon wafer substrate formed using a semiconductor process.

In an embodiment, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the invention is not limited thereto.

In an embodiment, the pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

In an embodiment, the circuit elements of the pixel circuit layer PCL may constitute a sub-pixel circuit SPC (see FIG. 2) of each of the sub-pixels SP shown in FIG. 3. In other words, the circuit elements of the pixel circuit layer PCL may be provided as transistors and one or more capacitors of the sub-pixel circuit SPC.

In an embodiment, the lines of the pixel circuit layer PCL may include lines connected to each of the sub-pixels SP. The lines of the pixel circuit layer PCL may include various signal lines and/or various voltage lines, which are necessary for driving the display element layer DPL.

In an embodiment, the display element layer DPL may be disposed on the pixel circuit layer PCL. The display element layer DPL may include light emitting elements of the sub-pixels SP.

In an embodiment, the light functional layer LFL may be disposed on the display element layer DPL. The light functional layer LFL may include light conversion patterns having color conversion particles and/or scattering particles. For example, color conversion particles may include quantum dots. The quantum dots may change a wavelength (or color) of light emitted from the display element layer DPL. The light functional layer LFL may further include light scattering patterns having scattering particles. In another embodiment, the light conversion patterns and the light scattering patterns may be omitted.

In an embodiment, the light functional layer LFL may further include a color filter layer including color filters. The color filter may allow light having a specific wavelength (or specific color) to be selectively transmitted therethrough. In other embodiments, the color filter layer may be omitted.

In an embodiment, a window for protecting an exposed surface (or top surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

FIG. 5 is a sectional view illustrating another embodiment of the display panel shown in FIG. 3.

In an embodiment and referring to FIG. 5, a display panel DP′ may include a substrate SUB, a pixel circuit layer PCL, a display element layer DPL, an input sensing layer SSL, and a light functional layer LFL. The substrate SUB, the pixel circuit layer PCL, the display element layer DPL, and the light functional layer LFL may be configured identically to the substrate SUB, the pixel circuit layer PCL, the display element layer DPL, and the light functional layer LFL, which are described with reference to FIG. 4, respectively. Hereinafter, overlapping descriptions will be omitted.

In an embodiment, the input sensing layer SSL may sense a user input with respect to a top surface (or display surface) of the display panel DP′. The input sensing layer SSL may include components suitable for sensing an external object such as a hand of a user or a pen. For example, the input sensing layer SSL may include touch electrodes.

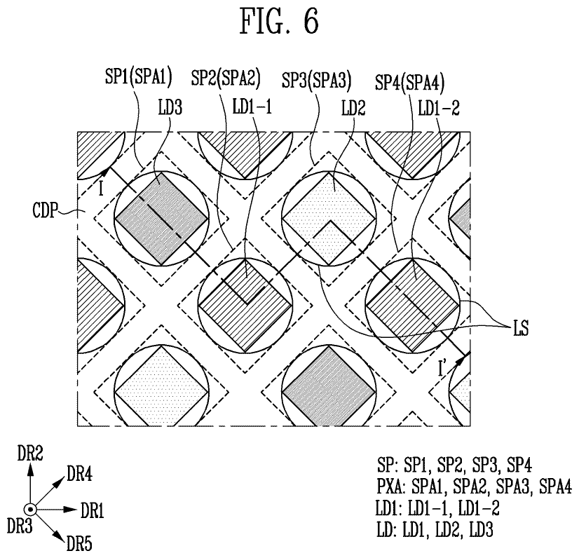

FIG. 6 is an enlarged plan view illustrating a portion of the display area of the display panel shown in FIG. 3, according to an embodiment.

In an embodiment and referring to FIG. 6, the display panel DP includes sub-pixels SP in the display area DA. In an embodiment, the sub-pixels SP may be arranged in a Pentile™ structure as a zigzag form along a fourth direction DR4 directed between the first direction DR1 and the second direction DR2 and a fifth direction DR5 directed to be orthogonal to the fourth direction DR4.

In an embodiment, the sub-pixels SP may include first to fourth sub-pixels SP1, SP2, SP3, and SP4, respectively. The sub-pixels SP1, SP2, SP3, and SP4 may be disposed in sub-pixel areas SPA1, SPA2, SPA3, and SPA4, respectively.

In an embodiment, light emitting elements LD may be disposed in the first to fourth sub-pixel areas SPA1, SPA2, SPA3, and SPA4, respectively. Specifically, a third light emitting element LD3 may be disposed in the first sub-pixel area SPA1, a (1-1)th light emitting element LD1-1 may be disposed in the second sub-pixel area SPA2, a second light emitting element LD2 may be disposed in the third sub-pixel area SPA3, and a (1-2)th light emitting element LD1-2 may be disposed in the fourth sub-pixel area SPA4. The (1-1)th light emitting element LD1-1 and the (1-2)th light emitting element LD1-2 may constitute a first light emitting element LD1. Each of the (1-1)th light emitting element LD1-1 and the (1-2)th light emitting element LD1-2 may generate light of a green color, the second light emitting element LD2 may generate light of a blue color, and the third light emitting element LD3 may generate light of a red color. However, the invention is not limited thereto.

In an embodiment, the light emitting elements LD1, LD2, and LD3 may be spaced apart from each other on a plane. That is, the light emitting elements LD1, LD2, and LD3 may not overlap with each other.

In an embodiment, conductive patterns CDP may be disposed between the light emitting elements LD1, LD2, and LD3. The conductive patterns CDP may be disposed between the light emitting elements LD1, LD2, and LD3 on a plane without overlapping with the light emitting elements LD1, LD2, and LD3. Also, the conductive patterns CDP may surround the first to fourth sub-pixel areas SPA1, SPA2, SPA3, and SPA4, respectively, without overlapping with the sub-pixel areas SPA1, SPA2, SPA3, and SPA4. That is, the conductive patterns CDP may be disposed between sub-pixel areas adjacent to each other among the sub-pixel areas SPA1, SPA2, SPA3, and SPA4.

In an embodiment, the conductive patterns CDP may have a mesh structure. The conductive patterns CDP may extend in the fourth direction DR4 or the fifth direction DR5, and intersect each other. The conductive patterns CDP may be entirely disposed in the display panel DP shown in FIG. 3 to transfer various signals including a voltage.

In an embodiment, lenses LS may be disposed above the light emitting elements LD1, LD2, and LD3. Each of the lenses LS may condense lights generated by each of the light emitting elements LD, thereby increasing the straightness of light, so that the light emission efficiency of each of the light emitting elements LD can be improved.

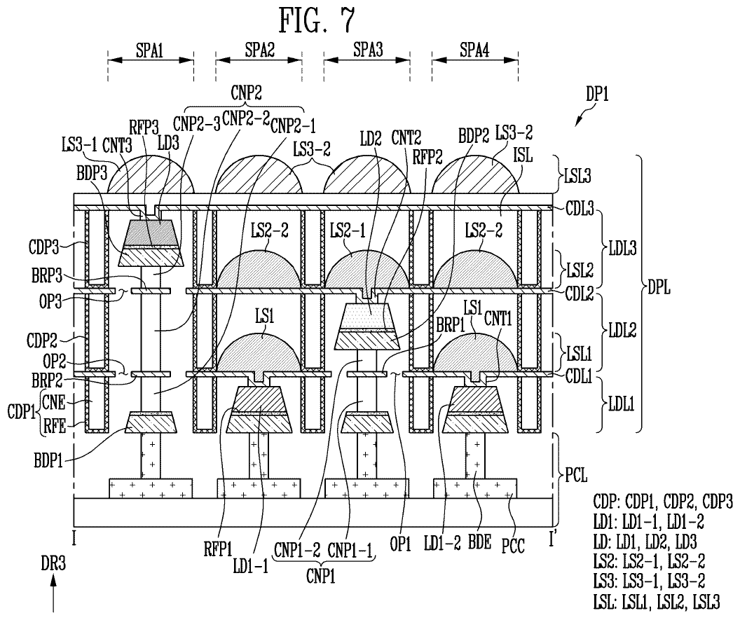

FIG. 7 is a sectional view taken along line I-I′ shown in FIG. 6, according to an embodiment. For example, FIG. 7 is a sectional view illustrating only a pixel circuit layer PCL and a display element layer DPL of a display panel DP1.

In an embodiment and referring to FIG. 7, the pixel circuit layer PCL may include pixel circuits PCC corresponding to the sub-pixel circuit SPC shown in FIG. 2, and bonding electrodes BDE.

In an embodiment, in the display area DA, the pixel circuits PCC may be disposed in the sub-pixel areas SPA1, SPA2, SPA3, and SPA4, respectively, and be spaced apart from each other. The bonding electrodes BDE may electrically connect the display element layer DPL respectively to the pixel circuits PCC. That is, since the pixel circuits PCC spaced apart from each other in the display area DA are insulated from each other, different voltages may be transferred to the display element layer DPL respectively through the bonding electrodes BDE.

In an embodiment, the display element layer DPL may be disposed on the pixel circuit layer PCL. The display element layer DPL may include a first light emitting element layer LDL1, a first conductive layer CDL1, a second light emitting element layer LDL2, a second conductive layer CDL2, a third light emitting element layer LDL3, a third conductive layer CDL3, and a lens layer LSL. In addition, the conductive patterns CDP shown in FIG. 6 may include first conductive patterns CDP1, second conductive patterns CDP2, and third conductive patterns CDP3.

In an embodiment, the first light emitting element layer LDL1 may be disposed on the pixel circuit layer PCL. The first light emitting element layer LDL1 may be connected to the pixel circuits PCC through the bonding electrodes BDE on the bonding electrodes BDE.

In an embodiment, the first light emitting element layer LDL1 may include first bonding patterns BDP1, first reflective patterns RFP1, at least one first light emitting element LD1, the first conductive patterns CDP1, a (1-1)th connection pattern CNP1-1, and a (2-1)th connection pattern CNP2-1.

In an embodiment, each of the first bonding patterns BDP1 may be connected to at least one of the bonding electrodes BDE, the first light emitting element LD1, the (1-1)th connection pattern CNP1-1, and the (2-1)th connection pattern CNP2-1. The first bonding pattern BDP1 may be disposed in the sub-pixel areas SPA1, SPA2, SPA3, and SPA4. Each of the first bonding patterns BDP1 may be provided as a double layer including titanium.

In an embodiment, the first reflective patterns RFP1 may be disposed on the first bonding patterns BDP1, respectively. The first reflective patterns RFP1 may overlap with the first bonding patterns BDP1, respectively. The first reflective patterns RFP1 may be made of a metal having a reflectivity greater than a reflectivity of the first bonding patterns BDP1. For example, each of the first reflective patterns RFP1 may include aluminum.

In an embodiment, the first light emitting element layer LDL1 may include at least one first light emitting element LD1. Hereinafter, a structure of the first light emitting element LD1 will be described.

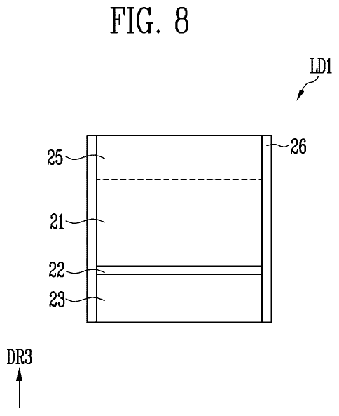

FIG. 8 is an enlarged sectional view illustrating the first light emitting element shown in FIG. 7, according to an embodiment.

In an embodiment and referring to FIG. 8, the first light emitting element LD1 may include a first semiconductor layer 21, an active layer 22, a second semiconductor layer 23, and an auxiliary layer 25. The first light emitting element LD1 may be implemented as a vertical light emitting stack structure in which the second semiconductor layer 23, the active layer 22, the first semiconductor layer 21, and the auxiliary layer 25 are sequentially stacked along the third direction DR3.

In an embodiment, the first semiconductor layer 21 may be configured to provide electrons. The first semiconductor layer 21 may include, for example, at least one N-type semiconductor layer. For example, the first semiconductor layer 21 may include any one semiconductor material among gallium nitride (GaN), aluminum gallium nitride (AlGaN), indium gallium nitride (InGaN), aluminum nitride (AlN), and indium nitride (InN), and be an N-type semiconductor layer doped with a first conductive dopant (or N-type dopant) such as silicon (Si), germanium (Ge) or tin (Sn). However, the material constituting the first semiconductor layer 21 is not limited thereto. In addition, various materials may constitute the first semiconductor layer 21. In an embodiment, the first semiconductor layer 21 may include a gallium nitride (GaN) semiconductor material doped with the first conductive dopant (or N-type dopant). In some embodiments, the first semiconductor layer 21 along with the auxiliary layer 25 may constitute an N-type semiconductor layer.

In an embodiment, the active layer 22 may be disposed on the first semiconductor layer 21 and may be an area in which electrons and holes are recombined. As electrons and holes are recombined in the active layer 22, light may be generated, which has a level changed to a low energy level and has a wavelength corresponding to the low energy level. The active layer 22 may be formed in a single quantum well structure or a multi-quantum well structure. When the active layer 22 is formed in the multi-quantum well structure, a unit including a barrier layer, a strain reinforcing layer, and a well layer may be repeatedly stacked, to form the active layer 22. However, embodiments of the active layer 22 are not limited thereto.

In an embodiment, the second semiconductor layer 23 may be disposed on the active layer 22 and may provide holes to the active layer 22. The second semiconductor layer 23 may include a semiconductor layer of which type is different from the type of the first semiconductor layer 21. In an example, the second semiconductor layer 23 may include at least one P-type semiconductor layer. For example, the second semiconductor layer 23 may include any one semiconductor material among gallium nitride (GaN), aluminum gallium nitride (AlGaN), indium gallium nitride (InGaN), aluminum nitride (AlN), and indium nitride (InN), and be a P-type semiconductor layer doped with a second conductive dopant (or P-type dopant) such as magnesium (Mg), zinc (Zn), calcium (Ca), strontium (Sr) or barium (Ba). However, the material constituting the second semiconductor layer 23 is not limited thereto. In addition, various materials may constitute the second semiconductor layer 23. In an embodiment, the second semiconductor layer 23 may include a gallium nitride (GaN) semiconductor material doped with the second conductive dopant (or P-type dopant).

In an embodiment, the bonding electrode BDE shown in FIG. 7 may be electrically connected to the second semiconductor layer 23. The bonding electrode BDE may include a eutectic metal.

In an embodiment, the auxiliary layer 25 may include a gallium nitride (GaN) semiconductor material undoped with an impurity. The auxiliary layer 25 along with the first semiconductor layer 21 may constitute an N-type semiconductor layer.

In an embodiment, the first light emitting element LD1 may further include an insulative film 26 covering an outer circumferential surface of the vertical light emitting stack structure. The insulative film 26 may prevent an electrical short circuit which may occur while the active layer 22 is in contact with another conductive material except the first and second semiconductor layers 21 and 23, respectively. The insulative film 26 may include a transparent insulating material. Also, the insulative film 26 is configured to expose a top surface of the auxiliary layer 25, which is to be in contact with the first conductive layer CDL1.

In an embodiment, second and third light emitting elements LD2 and LD3, respectively, may also be configured in the same structure as the first light emitting element LD1.

However, the invention is not limited thereto. In another embodiment, the first light emitting element LD1 may have a structure in which the structure shown in FIG. 8 is overturned in the opposite direction of the third direction DR3 (e.g., a structure in which the first semiconductor layer 21 is disposed at a lower portion and the second semiconductor layer 23 is disposed at an upper portion).

In an embodiment and referring back to FIG. 7, the first light emitting element layer LDL1 may include a (1-1)th light emitting element LD1-1 and a (1-2)th light emitting element LD1-2.

In an embodiment, the (1-1)th light emitting element LD1-1 and the (1-2)th light emitting element LD1-2 may be disposed on some first reflective patterns RFP1 among the first reflective patterns RFP1. The (1-1)th light emitting element LD1-1 may be disposed on a first reflective pattern RFP1 overlapping with the second sub-pixel area SPA2, and the (1-2)th light emitting element LD1-2 may be disposed on a first reflective pattern RFP1 overlapping with the fourth sub-pixel area SPA4. However, the invention is not limited thereto.

In an embodiment, the first reflective pattern RFP1 disposed under each of the (1-1)th light emitting element LD1-1 and the (1-2)th light emitting element LD1-2 may reflect light generated by each of the (1-1)th light emitting element LD1-1 and the (1-2)th light emitting element LD1-2 such that the light is emitted to a display surface of the display panel DP1.

In an embodiment, the (1-1)th light emitting element LD1-1 and the (1-2)th light emitting element LD1-2 may generate light of the same color. For example, the (1-1)th light emitting element LD1-1 and the (1-2)th light emitting element LD1-2 may generate light of a green color. Since the first light emitting element layer LDL1 is disposed lowermost with respect to a top surface of the display panel DP1, the first light emitting element LD1 generating light of a green color, of which luminance is highest, may be disposed in the first light emitting element layer LDL1. Also, since the first light emitting element layer LDL1 is disposed lowermost with respect to the top surface of the display panel DP1, two first light emitting elements LD1-1 and LD1-2 may be disposed in the first light emitting layer LDL1. However, the invention is not limited thereto.

In an embodiment, bonding electrodes BDE respectively overlapping with the (1-1)th light emitting element LD1-1 and the (1-2)th light emitting element LD1-2 may receive the first power voltage VDDN transferred from the pads PD shown in FIG. 3 to supply the first power voltage VDDN toward a P-type semiconductor layer of the first light emitting element LD.

In an embodiment, the first conductive patterns CDP1 may be disposed on the pixel circuit layer PCL. The first conductive patterns CDP1 may be spaced apart from the first light emitting element LD1 on a plane. Also, the first conductive patterns CDP1 may be spaced apart from the first bonding patterns BDP1 and the first reflective patterns RFP1 on a plane. The first conductive patterns CDP1 may be disposed between two sub-pixel areas adjacent to each other among the sub-pixel areas SPA1, SPA2, SPA3, and SPA4. That is, the first conductive patterns CDP1 may surround the first light emitting element LD1. The first conductive patterns CDP1 may overlap with the first bonding patterns BDP1, the first reflective patterns RFP1, the (1-1)th light emitting element LD1-1, and the (1-2)th light emitting element LD1-2 in a horizontal direction orthogonal to the third direction DR3.

In an embodiment, each of the first conductive patterns CDP1 may include a connection electrode CNE and a reflective electrode RFE. The connection electrode CNE may connect different electrodes, different patterns, and different layers to each other, thereby transferring various signals including a voltage. The connection electrode CNE may be made of a metal having conductivity. For example, the connection electrode CNE may include at least one of copper and tungsten.

In an embodiment, the reflective electrode RFE may cover at least a portion of the connection electrode CNE. For example, the reflective electrode RFE may cover a side surface of the connection electrode CNE. In another example, the reflective electrode RFE may cover side and bottom surfaces of the connection electrode CNE. Accordingly, the reflective electrode RFE may have a structure surrounding the first light emitting element LD1. Thus, the reflective electrode RFE reflects light generated by the first light emitting element LD1 at a side surface, thereby improving light emission efficiency.

In an embodiment, the reflective electrode RFE may be made of a metal having a reflectivity greater than a reflectivity of the connection electrode CNE. For example, the reflective electrode RFE may include at least one of aluminum and silver.

In an embodiment, the (1-1)th connection pattern CNP1-1 and the (2-1)th connection pattern CNP2-1 may be disposed on first reflective patterns RFP1 on which the first light emitting element LD1 is not disposed. The (1-1)th connection pattern CNP1-1 may overlap with the third sub-pixel area SPA3, and the (2-1)th connection pattern CNP2-1 may overlap with the fist sub-pixel area SPA1. That is, the (1-1)th connection pattern CNP1-1 may be connected to a first bonding pattern BDP1 and a first reflective pattern RFP1 in the third sub-pixel area SPA3, and the (2-1)th connection pattern CNP2-1 may be connected to a first bonding pattern BDP1 and a first reflective pattern RFP1 in the first sub-pixel area SPA1. The (1-1)th connection pattern CNP1-1 and the (2-1)th connection pattern CNP2-1 may overlap with the first conductive patterns CDP1 in the horizontal direction orthogonal to the third direction DR3.

In an embodiment, each of the (1-1)th connection pattern CNP1-1 and the (2-1)th connection pattern CNP2-1 may be made of the same material as the connection electrode CNE. For example, each of the (1-1)th connection pattern CNP1-1 and the (2-1)th connection pattern CNP2-1 may include at least one of copper and tungsten. However, the invention is not limited thereto.

In an embodiment, each of the (1-1)th connection pattern CNP1-1 and the (2-1)th connection pattern CNP2-1 may further include the same material as the reflective electrode RFE on at least one surface. For example, each of the (1-1)th connection pattern CNP1-1 and the (2-1)th connection pattern CNP2-1 may have the same structure as each of the first conductive patterns CDP1. However, the invention is not limited thereto, and the same material as the reflective electrode RFE disposed at the side surface in each of the (1-1)th connection pattern CNP1-1 and the (2-1)th connection pattern CNP2-1 may be omitted.

In an embodiment, the first conductive layer CDL1 may be disposed on the first light emitting element layer LDL1. The first conductive layer CDL1 may be connected to the (1-1)th light emitting LD1-1, the (1-2)th light emitting element LD1-2, the first conductive patterns CDP1, the (1-1)th connection pattern CNP1-1, and the (2-1)th connection pattern CNP2-1 while being in contact with the (1-1)th light emitting LD1-1, the (1-2)th light emitting element LD1-2, the first conductive patterns CDP1, the (1-1)th connection pattern CNP1-1, and the (2-1)th connection pattern CNP2-1.

In an embodiment, the first conductive layer CDL1 may be made of a conductive material. For example, the first conductive layer CDL1 may include indium tin oxide (ITO).

In an embodiment, the first conductive layer CDL1 may include a first bridge pattern BRP1 and may have a first opening OP1 defined at the periphery of the first bridge pattern BRP1. The first opening OP1 may have a ring shape surrounding the first bridge pattern BRP1. That is, the first bridge pattern BRP1 is not connected to other portions of the first conductive layer CDL1 but may be insulated from the other portions of the first conductive layer CDL1 due to the first opening OP1.

In an embodiment, the first bridge pattern BRP1 may overlap with the third sub-pixel area SPA3 and the second light emitting element LD2. The first bridge pattern BRP1 may be connected to the (1-1)th connection pattern CNP1-1 while being in contact with the (1-1)th connection pattern CNP1-1. The first bridge pattern BRP1 may entirely cover a top surface of the (1-1)th connection pattern CNP1-1. That is, an area of the first bridge pattern BRP1 may be greater than or equal to an area of the top surface of the (1-1)th connection pattern CNP1-1. As the first bridge pattern BRP1 entirely covers the top surface of the (1-1)th connection pattern CNP1-1, the (1-1)th connection pattern CNP1-1 is not exposed, so that corrosion of the (1-1)th connection pattern CNP1-1 can be prevented, and even a contact margin with a (1-2)th connection pattern CNP1-2 which will be described later can be secured.

In an embodiment, the first bridge pattern BRP1 may be connected to the second light emitting element LD2. The second light emitting element LD2 may be connected to the pixel circuit layer PCL through the first bridge pattern BRP1 and the (1-1)th connection pattern CNP1-1, and receive a signal transferred from the pixel circuit PCC.

In an embodiment, the first conductive layer CDL1 may include a second bridge pattern BRP2 spaced apart from the first bridge pattern BRP1, and have a second opening defined at the periphery of the second bridge pattern BRP2. The second opening OP2 may have a ring shape surrounding the second bridge pattern BRP2. That is, the second bridge pattern BRP2 is not connected to other portions of the first conductive layer CDL1 but may be insulated from the other portions of the first conductive layer CDL1 due to the second opening OP2.

In an embodiment, the second bridge pattern BRP2 may overlap with the first sub-pixel area SPA1 and the third light emitting element LD3. The second bridge pattern BRP2 may be connected to the (2-1)the connection pattern CNP2-1 while being in contact with the (2-1)the connection pattern CNP2-1. The second bridge pattern BRP2 may entirely cover a top surface of the (2-1)the connection pattern CNP2-1. That is, an area of the second bridge pattern BRP2 may be greater than or equal to an area of the top surface of the (2-1)the connection pattern CNP2-1.

In an embodiment, the second bridge pattern BRP2 may be electrically connected to the third light emitting element LD3. The third light emitting element LD3 may be connected to the pixel circuit layer PCL through the second bridge pattern BRP2 and the (2-1)th connection pattern CNP2-1, and receive a signal transferred from the pixel circuit PCC.

In an embodiment, the first conductive layer CDL1 except the first bridge pattern BRP1 and the second bridge pattern BRP2 may be in contact with the first light emitting element LD1 and the first conductive patterns CDP1. The first conductive layer CDL1 except the first bridge pattern BRP1 and the second bridge pattern BRP2 may receive a signal while connecting the first light emitting element LD1 and the first conductive patterns CDP to each other. The first conductive layer CDL1 may be in contact with the first light emitting element LD1 through a first contact hole CNT1. Specifically, the first conductive layer CDL1 may receive the second power voltage VSSN transferred from the common electrode CME shown in FIG. 3 to supply the second power voltage VSSN toward the N-type semiconductor layer of the first light emitting element LD1. Also, the first conductive layer CDL1 may electrically connect the first light emitting element layer LDL1 and the second light emitting element layer LDL2 to each other through the conductive patterns CDP.

In an embodiment, the second light emitting element layer LDL2 may be disposed on the first conductive layer CDL1. The second light emitting element layer LDL2 may include a second bonding pattern BDP2, a second reflective pattern RFP2, the second light emitting element LD2, the second conductive patterns CDP2, and a (2-2)th connection pattern CNP2-2.

In an embodiment, the second bonding pattern BDP2 may be connected to the first bridge pattern BRP1, the second light emitting element LD2, and the (1-2)th connection pattern CNP1-2. The second bonding pattern BDP2 may be disposed in the third sub-pixel area SPA3. The second bonding pattern BDP2 may be provided as a double layer including titanium.

In an embodiment, the second reflective pattern RFP2 may be disposed on the second bonding pattern BDP2. The second reflective pattern RFP2 may be made of a metal having a reflectivity greater than a reflectivity of the second bonding pattern BDP2. For example, the second reflective pattern RFP2 may include aluminum.

In an embodiment, the second light emitting element layer LDL2 may include at least one second light emitting element LD2. For example, the second light emitting element layer LDL2 may include one second light emitting element LD2.

In an embodiment, the second light emitting element LD2 may overlap with the third sub-pixel area SPA3. That is, the second light emitting element LD2 may be disposed at a position at which the second light emitting element LD2 is spaced apart from the (1-1)th light emitting element LD1-1 and the (1-2)th light emitting element LD1-2 on a plane. The second light emitting element LD2 does not overlap with the first light emitting element LD1, so that the light emission efficiency can be further improved.

In an embodiment, the second light emitting element LD2 may be disposed on the second reflective pattern RFP2. The second light emitting element LD2 may be disposed on the second reflective pattern RFP2 overlapping with the third sub-pixel area SPA3.

In an embodiment, the second light emitting element LD2 may generate light of a color different from the color of light generated by the first light emitting element LD1. For example, the second light emitting element LD2 may generate light of a blue color.

In an embodiment, the second conductive patterns CDP2 may be disposed on the pixel circuit layer PCL. The second conductive patterns CDP2 may be spaced apart from the second light emitting element LD2 on a plane. Also, the second conductive patterns CDP2 may also be spaced apart from the second bonding pattern BDP2 and the second reflective pattern RFP2, which overlap with the second light emitting element LD2, on a plane.

In an embodiment, the second conductive patterns CDP2 may be disposed between two sub-pixel areas adjacent to each other among the first to fourth sub-pixel areas SPA1, SPA2, SPA3, and SPA4. That is, the second conductive patterns CDP2 may surround the second light emitting element LD2. The second conductive patterns CDP2 may overlap with the first conductive patterns CDP1, respectively. Also, the second conductive patterns CDP2 may be electrically connected to the first conductive patterns CDP1 through the first conductive layer CDL1 while being in contact with the first conductive layer CDL1.

In an embodiment, the second conductive patterns CDP2 may overlap with the second bonding pattern BDP2, the second reflective pattern RFP2, and the second light emitting element LD2 in the horizontal direction directed orthogonal to the third direction DR3.

In an embodiment, each of the second conductive patterns CDP2 may include a connection electrode CNE and a reflective electrode RFE. That is, the second conductive patterns CDP2 may have the same structures as the first conductive patterns CDP1, respectively. Thus, the second conductive patterns CDP2 reflects light generated by the second light emitting element LD2 at side surfaces, thereby improving the light emission efficiency.

In an embodiment, the (1-2)th connection pattern CNP1-2 and the (2-2)th connection pattern CNP2-2 may be disposed on the (1-1)th connection pattern CNP1-1 and the (2-1)th connection pattern CNP2-1, respectively. The (1-2)th connection pattern CNP1-2 and the (2-2)th connection pattern CNP2-2 may be connected to the (1-1)th connection pattern CNP1-1 and the (2-1)th connection pattern CNP2-1 while overlapping with the (1-1)th connection pattern CNP1-1 and the (2-1)th connection pattern CNP2-1, respectively. The (1-2)th connection pattern CNP1-2 may be in contact with the first bridge pattern BRP1 in the third sub-pixel area SPA3, and be connected to the (1-1)th connection pattern CNP1-1 and the second light emitting element LD2 in the third sub-pixel area SPA3. The (2-2)th connection pattern CNP2-2 may be connected to the second bridge pattern BRP2 and the (2-1)th connection pattern CNP2-1 in the first sub-pixel area SPA1.

In an embodiment, the (1-2)th connection pattern CNP1-2 and the (2-2)th connection pattern CNP2-2 may be made of the same material as the (1-1)th connection pattern CNP1-1 and the (2-1)th connection pattern CNP2-1. For example, each of the (1-2)th connection pattern CNP1-2 and the (2-2)th connection pattern CNP2-2 may include at least one of copper and tungsten. However, the invention is not limited thereto.

Also, each of the (1-2)th connection pattern CNP1-2 and the (2-2)th connection pattern CNP2-2 may further include the same material as the reflective electrode RFE on at least one surface. For example, each of the (1-2)th connection pattern CNP1-2 and the (2-2)th connection pattern CNP2-2 may have the same structure as each of the second conductive patterns CDP2. However, the invention is not limited thereto, and the same material as the reflective electrode RFE disposed at the side surface in each of the (1-2)th connection pattern CNP1-2 and the (2-2)th connection pattern CNP2-2 may be omitted.

In an embodiment, the (1-1)th connection pattern CNP1-1 and the (1-2)th connection pattern CNP1-2 may include the same material, and be connected to each other through the first conductive layer CDL1, e.g., the first bridge pattern BRP1. The (1-1)th connection pattern CNP1-1 and the (1-2)th connection pattern CNP1-2 may constitute one first connection pattern CNP1. The first connection pattern CNP1 may overlap with the second light emitting element LD2, and connect the pixel circuit layer PCL and the second light emitting element LD2 to each other. That is, the connection pattern CNP1 may transfer a signal transferred from the pixel circuit PCC to the second light emitting element LD2. Specifically, the first connection pattern CNP1 in contact with the second light emitting element LD2 may receive the first power voltage VDDN from the pads PD shown in FIG. 3 and the pixel circuit layer PCL to supply the first power voltage VDDN toward a P-type semiconductor layer of the first light emitting element LD1.

In an embodiment, the second conductive layer CDL2 may be disposed on the second light emitting element layer LDL2. The second conductive layer CDL2 may be connected to the second light emitting element LD2, the second conductive patterns CDP2, and the (2-2)th connection pattern CNP2-2 while being in contact with the second light emitting element LD2, the second conductive patterns CDP2, and the (2-2)th connection pattern CNP2-2.

In an embodiment, the second conductive layer CDL2 may be made of a conductive material. For example, the second conductive layer CDL2 may include indium tin oxide (ITO).

The second conductive layer CDL2 may include a third bridge pattern BRP3, and have a third opening OP3 defined at the periphery of the third bridge pattern BRP3. The third opening OP3 may have a ring shape surrounding the third bridge pattern BRP3. That is, the third bridge pattern BRP3 is not connected to other portions of the third conductive layer CDL3 but may be insulated from the other portions of the third conductive layer CDL3 due to the third opening OP3.

In an embodiment, the third bridge pattern BRP3 may overlap with the first sub-pixel area SPA1 and the third light emitting element LD3. The third bridge pattern BRP3 may be connected to the (2-2)th connection pattern CNP2-2 while being in contact with the (2-2)th connection pattern CNP2-2. The third bridge pattern BRP3 may entirely cover a top surface of the (2-2)th connection pattern CNP2-2. That is, an area of the third bridge pattern BRP3 may be greater than or equal to an area of the top surface of the (2-2)th connection pattern CNP2-2.

Also, the third bridge pattern BRP3 may be connected to the third light emitting element LD3. The third light emitting element LD3 may be connected to the pixel circuit layer PCL through the third bridge pattern BRP3, the (2-1)th connection pattern CNP2-1, and the (2-2)th connection pattern CNP2-2, and receive a signal transferred from the pixel circuit PCC.

In an embodiment, the second conductive layer CDL2 except the third bridge pattern BRP3 may be in contact with the second light emitting element LD2 and the second conductive patterns CDP2. The second conductive layer CDL2 except the third bridge pattern BRP3 may transfer a signal while connecting the second light emitting element LD2 and the second conductive patterns CDP2 to each other. The second conductive layer CDL may be in contact with the second light emitting element LD2 through a second contact hole CNT2. Specifically, the second conductive layer CDL2 may receive the second power voltage VSSN transferred from the common electrode CME shown in FIG. 3 to supply the second power voltage VSSN toward an N-type semiconductor layer of the second light emitting element LD2. Also, the second conductive layer CDL2 may electrically connect to the second light emitting element layer LDL2 and the third light emitting element layer LDL3 to each other.

In an embodiment, the third light emitting element LDL3 may be disposed on the second conductive layer CDL2. The third light emitting element layer LDL3 may include a third bonding pattern BDP3, a third reflective pattern RFP3, the third light emitting element LD3, the third conductive patterns CDP3, and a (2-3)th connection pattern CNP2-3.

In an embodiment, the third bonding pattern BDP3 may be connected to the third bridge pattern BRP3, the third light emitting element LD3, and the (2-2)th connection pattern CNP2-2. The third bonding pattern BDP3 may be disposed in the first sub-pixel area SPA1. The third bonding pattern BDP3 may be provided as a double layer including titanium.

In an embodiment, the third reflective pattern RFP3 may be disposed on the third bonding pattern BDP3. The third reflective pattern RFP3 may be made of a metal having a reflectivity greater than a reflectivity of the third bonding pattern BDP3. For example, the third reflective pattern RFP3 may include aluminum.

In an embodiment, the third light emitting element layer LDL3 may include at least one third light emitting element LD3. For example, the third light emitting element layer LDL3 may include one third light emitting element LD3.

In an embodiment, the third light emitting element LD3 may overlap with the first sub-pixel area SPA1. That is, the third light emitting element LD3 may be disposed at a position at which the third light emitting element LD3 is spaced apart from all of the (1-1)th light emitting element LD1-1, the (1-2)th light emitting element LD1-2, and the second light emitting element LD2 on a plane. The third light emitting element LD3 does not overlap with the first light emitting element LD1 and the second light emitting element LD2, so that the light emission efficiency can be further improved.

In an embodiment, the third light emitting element LD3 may be disposed on the third reflective pattern RFP3. The third light emitting element LD3 may be disposed on the third reflective pattern RFP3 overlapping with the first sub-pixel area SPA1.

In an embodiment, the third light emitting element LD3 may generate light of a color different from the colors of lights generated by the first light emitting element LD1 and the second light emitting element LD2. For example, the third light emitting element LD3 may generate light of a red color.

In an embodiment, the third conductive patterns CDP3 may be disposed on the pixel circuit layer PCL. The third conductive patterns CDP3 may be spaced apart from the third light emitting element LD3 on a plane. Also, the third conductive patterns CDP3 may also be spaced apart from the third bonding pattern BDP3 and the third reflective pattern RFP3, which overlap with the third light emitting element LD3.

The third conductive patterns CDP3 may be disposed between two sub-pixel areas adjacent to each other among the sub-pixel areas SPA1, SPA2, SPA3, and SPA4. That is, the third conductive patterns CDP3 may surround the third light emitting element LD3. The third conductive patterns CDP3 may overlap with the second conductive patterns CDP2, respectively. Also, the third conductive patterns CDP3 may be electrically connected to the second conductive patterns CDP2 through the second conductive layer CDL2 while being in contact with the second conductive layer CDL2.

The third conductive patterns CDP3 may overlap with the third bonding pattern BDP3, the third reflective pattern RFP3, and the third light emitting element LD3 in the horizontal direction orthogonal to the third direction DR3.

In an embodiment, each of the third conductive patterns CDP3 may include a connection electrode CNE and a reflective electrode RFE. That is, the third conductive patterns CDP3 may have the same structures as the first conductive patterns CDP1, respectively. Thus, the third conductive patterns CDP3 reflects light generated by the third light emitting element LD3 at side surfaces, thereby improving the light emission efficiency.

In an embodiment, the (2-3)th connection pattern CNP2-3 may be disposed on the (2-2)th connection pattern CNP2-2. The (2-3)th connection pattern CNP2-3 may be connected to the (2-1)th connection pattern CNP2-1 and the (2-2)th connection pattern CNP2-2 while overlapping with the (2-1)th connection pattern CNP2-1 and the (2-2)th connection pattern CNP2-2. The (2-3)th connection pattern CNP2-3 may be in contact with the third bridge pattern BRP3 in the first sub-pixel area SPA1, and be connected to the (2-2)th connection pattern CNP2-2 and the third light emitting element LD3 in the first sub-pixel area SPA1.

In an embodiment, the (2-3)th connection pattern CNP2-3 may be made of the same material as the (2-2)th connection pattern CNP2-2. For example, the (2-3)th connection pattern CNP2-3 may include at least one of copper and tungsten. However, the invention is not limited thereto.

In an embodiment, t, the (2-3)th connection pattern CNP2-3 may further include the same material as the reflective electrode on at least one side surface. For example, the (2-3)th connection pattern CNP2-3 may have the same structure as each of the third conductive patterns CDP3. However, the invention is not limited thereto, and the same material as the reflective electrode RFE disposed at the side surface in the (2-3)th connection pattern CNP2-3 may be omitted.

In an embodiment, the (2-2)th connection pattern CNP2-2 and the (2-3)th connection pattern CNP2-3 may include the same material, and be connected to each other the second conductive layer CDL2, e.g., the third bridge pattern BRP3. Similarly, the (2-1)th connection pattern CNP2-1 and the (2-2)th connection pattern CNP2-2 may include the same material, and be connected to each other through the first conductive layer CDL1, e.g., the second bridge pattern BRP2. The (2-1)th connection pattern CNP2-1, the (2-2)th connection pattern CNP2-2), and the (2-3)th connection pattern CNP2-3 may constitute one connection pattern CNP2. The second connection pattern CNP2 may overlap with the third light emitting element LD3, and connect the pixel circuit layer PCL and the third light emitting element LD3 to each other. That is, the second connection pattern CNP2 may transfer a signal transferred from the pixel circuit PCC to the third light emitting element LD3. Specifically, the second connection pattern CNP2 in contact with the third light emitting element LD3 may receive the first power voltage VDDN transferred from the pads PD shown in FIG. 3 and the pixel circuit layer PCL to supply the first power voltage VDDN toward a P-type semiconductor layer of the third light emitting element LD3.

In an embodiment, the third conductive layer CDL3 may be disposed on the third light emitting element LD3. The third conductive layer CDL3 may be connected to the third light emitting element LD3 and the third conductive patterns CDP3 while being in contact with the third light emitting element LD3 and the third conductive patterns CDP3.

The third conductive layer CDL3 may be made of a conductive material. For example, the third conductive layer CDL3 may include indium tin oxide (ITO).

Unlike the first conductive layer CDL1 and the second conductive layer CDL2, the third conductive layer CDL3 includes no insulated bride pattern, and may entirely extend in the display panel DP1.

The third conductive layer CDL3 may transfer a signal while connecting the third light emitting element LD3 and the third conductive patterns CDP3 to each other. The third conductive layer CDL3 may be in contact with the third light emitting element LD3 through a third contact hole CNT3. Specifically, the third conductive layer CDL3 may receive the second power voltage VSSN transferred from the common electrode CME shown in FIG. 3 to supply the second power voltage VSSN toward an N-type semiconductor layer.

In an embodiment, each of the pixel circuit layer PCL and the first to third light emitting element layers LDL1, LDL2, and LDL3 may include an insulating layer ISL disposed between each of light emitting elements, electrodes, and patterns, which are included in each layer. For example, the insulating layer ISL may include oxide.

In an embodiment, a first lens layer LSL1 may be disposed between the first light emitting element layer LDL1 and the second light emitting element layer LDL2. For example, the first lens layer LSL1 may be disposed between the first conductive layer CDL1 and the second light emitting element layer LDL2. That is, the first lens layer LSL1 may be disposed in the same layer as the second light emitting element layer LDL2.

The first lens layer LSL1 may include at least one lens which refracts incident light and overlaps with at least one first light emitting element LD1. That is, the first lens layer LSL1 may include first lenses LS1 respectively overlapping with the (1-1)th light emitting element LD1-1 and the (1-2)th light emitting element LD1-2. That is, the first lenses LS1 may overlap with the second sub-pixel area SPA2 and the fourth sub-pixel area SPA4, respectively.

Each of the first lenses LS1 may have a hemispherical shape. However, the invention is not limited thereto, and each of the first lenses LS1 may have a shape obtained by cutting a portion of a spherical shape on a plane.

In an embodiment, each of the first lenses LS1 may be a convex lens. For example, the first lenses LS1 may have a shape convex in the third direction DR3. A refractive index of a material constituting each of the first lenses LS1 may be higher than a refractive index of the material constituting the insulating layer ISL.

In an embodiment, each of the (1-1)th light emitting element LD1-1 and the (1-2)th light emitting element LD1-2 may emit light radially. Since each of the first lenses LS1 is a convex lens, each of the first lenses LS1 may condense lights emitted from each of the (1-1)th light emitting element LD1-1 and the (1-2)th light emitting element LD1-2, thereby allowing the lights to be emitted to the display surface of the display panel DP1. A path of light emitted radially from each of the (1-1)th light emitting element LD1-1 and the (1-2)th light emitting element LD1-2 may be changed to a path through which light goes straight in the third direction DR3 while passing through each of the first lenses LS1. That is, the first lenses LS1 can increase the straightness of light emitted from each of the (1-1)th light emitting element LD1-1 and the (1-2)th light emitting element LD1-2 in a vertical direction (i.e., the third direction DR3).

Specifically, in an embodiment, light emitted from each of the (1-1)th light emitting element LD1-1 and the (1-2)th light emitting element LD1-2 may be reflected from the first reflective patterns RFP1 respectively disposed under the (1-1)th light emitting element LD1-1 and the (1-2)th light emitting element LD1-2 and the reflective electrode RFE included in each of the first conductive patterns CDP1 respectively surrounding the (1-1)th light emitting element LD1-1 and the (1-2)th light emitting element LD1-2, or be incident immediately onto the first lenses LS1. The first lenses LS1 may condense not only light incident immediately onto the first lenses LS1 but also light reflected from the first reflective patterns RFP1 and the reflective electrode RFE included in each of the first conductive patterns CDP1 to be incident onto the first lenses LS1, thereby allowing the condensed light to be emitted in the third direction DR3 as the vertical direction.

In an embodiment, each of the first lenses LS1 may include an inorganic material. However, the invention is not limited thereto.

In an embodiment, the first lenses LS1 included in the first lens layer LSL1 may be disposed to be spaced apart from each other. That is, the first lenses LS1 may be disposed between second conductive patterns CDP2 adjacent to each other to be spaced apart from each other. However, the invention is not limited thereto. In another embodiment, the first lens layer LSL1 may be integrally formed. That is, the first lenses LS1 included in the first lens layer LSL1 may be connected to each other on the first conductive layer CDL1. A portion of the first lens layer LSL1, which overlaps with each of the first sub-pixel area SPA1 and the third sub-pixel area SPA3, in which the first lenses LS1 are not disposed, may have a planarized top surface, and include a contact hole overlapping with each of the second conductive patterns CDP2, the (1-2)th connection pattern CNP1-2, and the (2-2)th connection pattern CNP2-2.

In an embodiment, a second lens layer LSL2 may be disposed between the second light emitting element layer LDL2 and the third light emitting element layer LDL3. For example, the second lens layer LSL2 may be disposed between the second conductive layer CDL2 and the third light emitting element layer LDL3. That is, the second lens layer LSL2 may be disposed in the same layer as the third light emitting element layer LDL3.

In an embodiment, the second lens layer LSL2 may include second lenses LS2 which refract incident light. The second lenses LS2 may include a (2-1)th lens LS2-1 and (2-2)th lenses LS2-2. The (2-1)th lens LS2-1 may overlap with the second light emitting element LD2. That is, the (2-1)th lens LS2-1 may overlap with the third sub-pixel area SPA3. The (2-2)th lenses LS2-2 may overlap with the (1-1)th light emitting element LD1-1 and the (1-2)th light emitting element LD1-2, respectively. That is, the (2-2)th lenses LS2-2 may overlap with the second sub-pixel area SPA2 and the fourth sub-pixel area SPA4, respectively.

In an embodiment, each of the second lenses LS2 may have a hemisphere shape. However, the invention is not limited thereto, and each of the second lenses LS2 may have a shape obtained by cutting a portion of a spherical shape on a plane.

In an embodiment, each of the second lenses LS2 may be a convex lens. For example, the second lenses LS2 may have a convex shape in the third direction DR3. A refractive index of a material constituting each of the second lenses LS2 may be higher than the refractive index of the material constituting the insulating layer ISL.

In an embodiment, the second light emitting element LD2 may emit light radially. Since the (2-1)th lens LS2-1 is a convex lens, the (2-1)th lens LS2-1 may condense lights emitted from the second light emitting element LD2, thereby allowing the lights to be emitted to the display surface of the display panel DP1. A path of light emitted radially from the second light emitting element LD2 may be changed to a path through which light goes straight in the third direction DR3 while passing through the (2-1)th lens LS2-1. That is, the (2-1)th lens LS2-1 can increase the straightness of light emitted from the second light emitting element LD2 in the vertical direction (i.e., the third direction DR3).

Specifically, in an embodiment, light emitted from the second light emitting element LD2 may be reflected from the second reflective pattern RFP2 disposed under the second light emitting element LD2 and the reflective electrode RFE included in each of the second conductive patterns CDP2 surrounding the second light emitting element LD2, or be incident immediately onto the (2-1)th lens LS2-1. The (2-1)th lens LS2-1 may condense not only light incident immediately onto the (2-1)th lens LS2-1 but also light reflected from the second reflective pattern RFP2 and the reflective electrode RFE included in each of the second conductive patterns CDP2 to be incident onto the (2-1)th lens LS2-1, thereby allowing the condensed light to be emitted in the third direction DR3 as the vertical direction.

In addition, in an embodiment, as the (2-2)th lenses LS2-2 overlap with the (1-1)th light emitting element LD1-1 and the (1-2)th light emitting element LD1-2, respectively, the (2-2)th lenses LS2-2 may condense light passing through the first lenses LS1 once more, thereby allowing the condensed light to be emitted in the third direction DR3 as the vertical direction. That is, the (2-2)th lenses LS2-2 can secondarily increase the straightness of light emitted from the (1-1)th light emitting element LD1-1 and the (1-2)th light emitting element LD1-2 through the (2-2)th lenses LS2-2.

In an embodiment, each of the second lenses LS2 may include the same material as each of the first lenses LS1. That is, each of the second lenses LS2 may include an inorganic material. However, the invention is not limited thereto.

In an embodiment, the second lenses LS2 included in the second lens layer LSL2 may be disposed to be spaced apart from each other. That is, the second lenses LS2 may be disposed between third conductive patterns CDP3 adjacent to each other to be spaced apart from each other. However, the invention is not limited thereto. In another embodiment, the second lens layer LSL2 may be integrally formed. That is, the second lenses LS2 included in the second lens layer LS2 may be connected to each other on the second conductive layer CDL2. A portion of the second lens layer LSL2, which overlaps with the first sub-pixel area SPA1 in which the second lenses LS2 are not disposed, may have a planarized top surface, and include a contact hole overlapping with each of the third conductive patterns CDP3 and the (2-3)th connection pattern CNP2-3.

In an embodiment, a third lens layer LSL3 may be disposed on the third light emitting layer LDL3. For example, the third lens layer LSL3 may be disposed on the third conductive layer CDL3 and the insulating layer ISL.

In an embodiment, the third lens layer LSL3 may include third lenses LS3 which refract incident light. The third lenses LS3 may include a (3-1)th lens LS3-1 and (3-2)th lenses LS3-2. The (3-1)th lens LS3-1 may overlap with the third light emitting element LD3. That is, the (3-1)th lens LS3-1 may overlap with the first sub-pixel area SPA1. The (3-2)th lenses LS3-2 may overlap with the (1-1)th light emitting element LD1-1, the (1-2)th light emitting element LD1-2, and the second light emitting element LD2, respectively. That is, the (3-2)th lenses LS3-2 may overlap with the sub-pixel areas SPA2, SPA3, and SPA4, respectively.

In an embodiment, each of the third lenses LS3 may have a hemispherical shape. However, the invention is not limited thereto, and each of the third lenses LS3 may have a shape obtained by cutting a portion of a spherical shape on a plane.

In an embodiment, each of the third lenses LS3 may be a convex lens. For example, the third lenses LS3 may have a shape convex in the third direction DR3. A refractive index of a material constituting each of the third lenses LS3 may be higher than the refractive index of the material constituting the insulating layer ISL.

In an embodiment, the third light emitting element LD3 may emit light radially. Since the (3-1)th lens LS3-1 is a convex lens, the (3-1)th lens LS3-1 may condense lights emitted from the third light emitting element LD3, thereby allowing the lights to be emitted to the display surface of the display panel DP1. A path of light emitted radially from the third light emitting element LD3 may be changed to a path through which light goes straight in the third direction DR3 while passing through the (3-1)th lens LS3-1. That is, the (3-1)th lens LS3-1 can increase the straightness of light emitted from the third light emitting element LD3 in the vertical direction (i.e., the third direction DR3).

Specifically, in an embodiment, light emitted from the third light emitting element LD3 may be reflected from the third reflective pattern RFP3 disposed under the third light emitting element LD3 and the reflective electrode RFE included in each of the third conductive patterns CDP3 surrounding the third light emitting element LD3, or be incident immediately onto the (3-1)th lens LS3-1. The (3-1)th lens LS3-1 may condense not only light incident immediately onto the (3-1)th lens LS3-1 but also light reflected from the third reflective pattern RFP3 and the reflective electrode RFE included in each of the third conductive patterns CDP3 to be incident onto the (3-1)th lens LS3-1, thereby allowing the condensed light to be emitted in the third direction DR3 as the vertical direction.

In addition, in an embodiment, as the (3-2)th lenses LS3-2 overlap with the (1-1)th light emitting element LD1-1, the (1-2)th light emitting element LD1-2, and the second light emitting element LD2, respectively, the (3-2)th lenses LS3-2 may condense light passing through the first lenses LS1 and the second lenses LS2 once more, thereby allowing the condensed light to be emitted in the third direction DR3 as the vertical direction. That is, the (3-2)th lenses LS3-2 can secondarily increase the straightness of light emitted from the (1-1)th light emitting element LD1-1, the (1-2)th light emitting element LD1-2, and the second light emitting element LD2 through the (3-2)th lenses LS3-2.

In an embodiment, each of the third lenses LS3 may include a material different from the material of each of the first lenses LS1 and the second lenses LS2. That is, each of the third lenses LS3 may include an inorganic material. However, the invention is not limited thereto.

The third lenses LS3 included in the third lens layer LSL3 may be disposed to be spaced apart from each other.

However, the invention is not limited thereto. In another embodiment, the third lens layer LSL3 may include a third lens LS3 overlapping with only some of the light emitting elements LD1 to LD3. For example, the third lens layer LSL3 may include one (3-1)th lens LS3-1 overlapping with the third light emitting element LD3.

In accordance with an embodiment, the display device further includes the lens layers LS1, LS2, and LS3 respectively between the light emitting element layers LDL1, LDL2, and LDL3 and on the third light emitting element layer LDL3, so that a focal distance as a distance between each of the light emitting elements LD1, LD2, and LD3 and each of the lenses can be decreased. Specifically, a distance between the first light emitting element LD1 disposed lowermost and the first lens LS1, a distance between a distance between the second light emitting element LD2 and the second lens LS2, and a distance between the third light emitting element LD3 and the third lens LS3 can be minimized. Thus, a difference between optical paths of the light emitting elements LD1, LD2, and LD3, which are caused due to the stacked structure of the light emitting elements LD1, LD2, and LD3, can be compensated through the lenses included in the lenses LSL1, LSL2, and LSL3. Accordingly, the light emission efficiency of the display panel DP1 can be maximized.

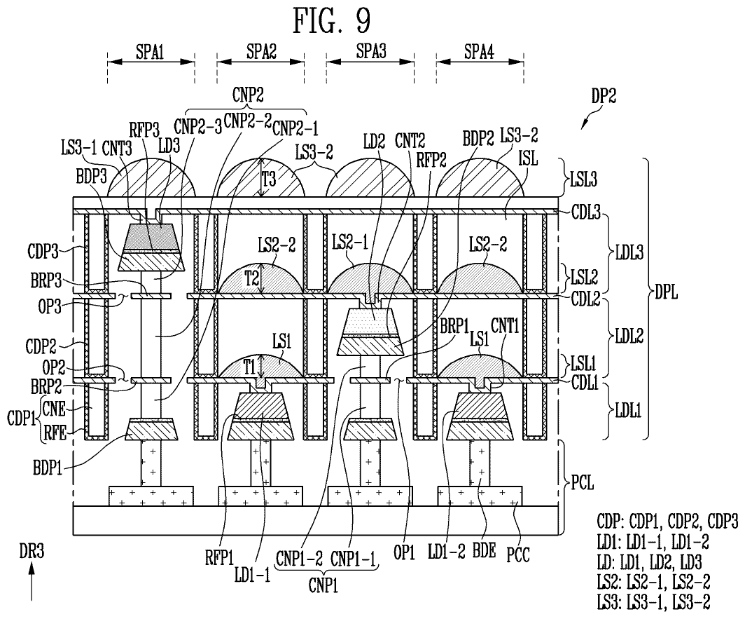

FIGS. 9 to 17 are sectional views illustrating other embodiments of FIG. 7.

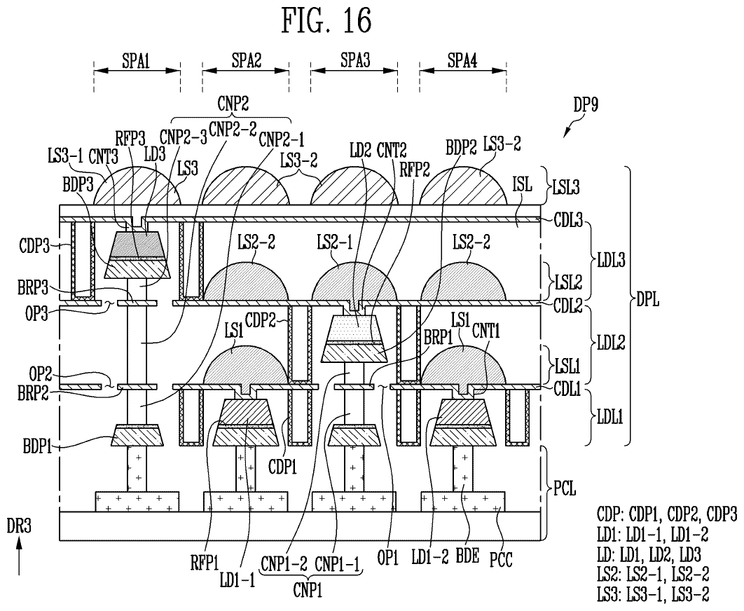

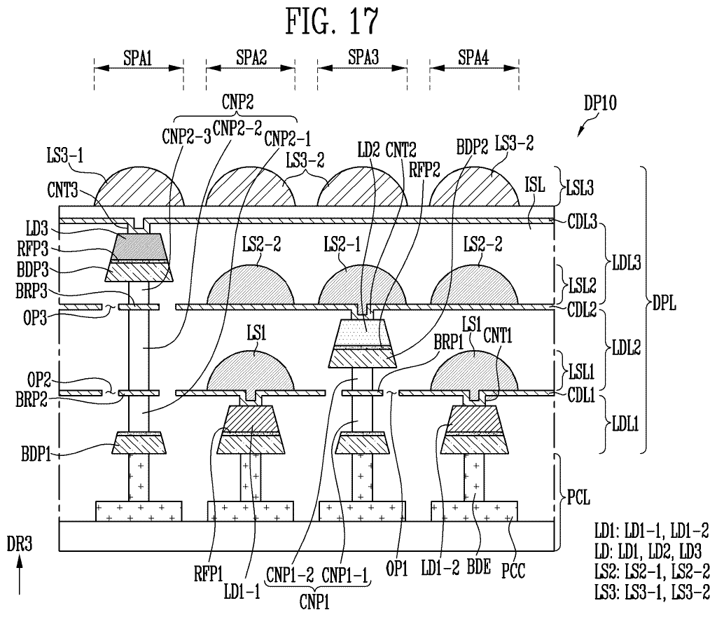

In an embodiment according to each of FIGS. 9 to 15, shapes of lenses included in the lens layers LSL1, LSL2, and LSL3 are different from one another. In an embodiment according to each of FIGS. 16 and 17, at least some of the conductive patterns CDP1 to CDP3 may be omitted. In FIGS. 9 to 17, descriptions of portions overlapping with the above-described portion will be simplified or will not be repeated.

In an embodiment and referring to FIGS. 9 to 17, at least some of the lenses included in the lens layers LSL1, LSL2, and LSL3 may have a shape different from a shape of the others of the lens layers LSL1, LSL2, and LSL3. The shapes of the lenses included in the lens layers LSL1, LSL2, and LSL3 may be different from each other according to a characteristic of a light emitting element LD located under each of the lenses and a distance between the lenses. That is, the shapes of the lenses may be adjusted differently from each other, and therefore, the shape of each of the lenses may be optimized suitable for a light emitting element LD. The shape of each of the lenses may be determined by synthetically considering a thickness of an N-type semiconductor layer included in the light emitting element LD, a thickness of each lens, and a distance between the light emitting element LD and each lens. Accordingly, the shape of each of the lenses is optimized suitable for the light emitting element LD, so that the light emission efficiency of each of light emitting elements LD can be maximized.

In an embodiment, that the shapes of the lenses are different from each other may mean that a shape of a spherical surface of each of the lenses, a size of each of the lenses, a curvature of each of the lenses, or the like, create a condition which has influence on a path of light generated by the light emitting element LD varies.

In an embodiment and referring to FIG. 9, in a display panel DP2, at least some of lenses included in the lens layers LSL1, LSL2, and LSL3 may have a curvature different from a curvature of the others of the lenses included in the lens layers LSL1, LSL2, and LSL3, and have a shape of a spherical surface, which is different from a shape of a spherical surface of the others of the lenses included in the lens layers LSL1, LSL2, and LSL3.

For example, in an embodiment, first lenses LS1 included in the first lens layer LSL1 may have the same shape, second lenses LS2 included in the second lens layer LSL2 may have the same shape, and third lenses LS3 included in the third lens layer LSL3 may have the same shape.

Since the first lenses LS1 included in the first lens layer LSL1 have the same conditions such as a distance from the first light emitting element LD1 and a distance from a top surface of the display element layer DPL, the first lenses LS1 may be formed in the same shape.

Similarly, in an embodiment, since the (2-2)th lenses LS2-2 included in the second lens layer LSL2 also have the same conditions such as a distance from the first light emitting element LD1 and a distance from a top surface of the display element layer DPL, the (2-2)th lenses LS2-2 may have the same shape.

In an embodiment, in the (2-1)th lens LS2-1 and the (2-2)th lenses LS2-2, which are included in the second lens layer LSL2, a distance of the (2-1)th lens LS2-1 from a light emitting element LD disposed thereunder may be different from a distance of each of the (2-2)th lenses LS2-2 from a light emitting element LD disposed thereunder. However, the (2-1)th lens LS2-1 and the (2-2)th lenses LS2-2 have the same distance up to the top surface of the display element layer DPL, and the efficiency of processes may be improved when lenses disposed in the same layer have the same shape. Therefore, the (2-1)th lens LS2-1 and the (2-2)th lenses LS2-2 may be formed in the same shape.

Similarly, in an embodiment, in the third lenses LS3 included in the third lens layer LSL3, a distance of one third lens LS3 from a light emitting element LD disposed thereunder may be different from a distance of another third lens LS3 from a light emitting element LD disposed thereunder. The third lenses LS3 may be located in the same layer, and the efficiency of processes may be improved when lenses disposed in the same layer have the same shape. Therefore, the third lenses LS3 may be formed in the same shape.

However, in an embodiment, since the first lenses LS1, the second lenses LS2, and the third lenses LS3 have different distances between light emitting elements LD and the lenses and different distances between the top surface of the display element layer DPL and the lenses as conditions which have influence on a path of light generated by each light emitting element LD, and are formed through different processes, the first lenses LS1, the second lenses LS2, and the third lenses LS3 may have different shapes.

That is, the first lenses LS1 may have a shape different from shapes of the second lenses LS2 and the third lenses LS3, and the second lenses LS2 may have a shape different from a shape of the third lenses LS3.

For example, in an embodiment, the lenses LS1 to LS3 may have different curvatures, different curvature radii, different shapes of spherical surfaces, and different heights.

In an embodiment, a curvature of each of the first lenses LS1 may be smaller than a curvature of each of the second lenses LS2 and the third lenses LS3. That is, a curvature radius of each of the first lenses LS1 may be greater than a curvature radius of each of the second lenses LS2 and the third lenses LS3. In addition, a curvature of each of the second lenses LS2 may be smaller than a curvature of each of the third lenses LS3. That is, a curvature radius of each of the second lenses LS2 may be greater than a curvature radius of each of the third lenses LS3.

In an embodiment, as a curvature becomes smaller, i.e., as a curvature radius becomes greater, the lenses may make the light to be more parallel. That is, as a lens has a smaller curvature and a greater curvature radius, the lens may make incident light to be more parallel and be sent farther. Therefore, the curvature of each of the first lenses LS1 located above the first light emitting element LD1 located lowermost may be smallest, and the curvature radius of each of the first lenses LS1 may be greatest. Accordingly, the first lenses LS1 among the first to third lenses LS1 to LS3 may sent incident light farthest.

In addition, in an embodiment, as the curvature becomes greater, i.e., as the curvature radius becomes smaller, the light condensing power of incident light may be improved. That is, as a lens has a greater curvature and a smaller curvature radius, the lens may more strongly condense the incident light. Therefore, the curvature of each of the third lenses LS3 located above the third light emitting element LD3 which is located uppermost and has decreased light emission efficiency may be greatest, and the curvature radius of each of the third lenses LS3 may be smallest. Accordingly, the third lenses LS3 among the lenses LS1 to SL3 may most strongly condense the incident light.

In addition, in an embodiment, each of the first lenses LS1 may have a first height T1. Each of the second lenses LS2 may have a second height T2. Each of the third lenses LS3 may have a third height T3. The first height T1 may be smallest, and the third height T3 may be greatest. Accordingly, since the first height T1 of each of the first lenses LS1 is smallest, heights of the first lens layer LSL1 and the second light emitting element layer LDL2 may be decreased. Therefore, the optical path of the first light emitting element LD1 may be reduced. Since the optical path of the first light emitting element LD1 is reduced, the light emission efficiency of the first light emitting element LD1 may be improved. Like the first lenses LS1, the second lenses LS2 may reduce the optical path of the second light emitting element LD2, thereby improving the light emission efficiency of the second light emitting element LD2.

In an embodiment, since the lenses LS1 to LS3 have different curvatures, different curvature radii, and different heights, shapes of spherical surfaces of the lenses LS1 to LS3 may be different from one another according to the curvatures and the heights. However, the invention is not limited thereto, and each of the lenses LS1 to LS3 may have an elliptical shape.

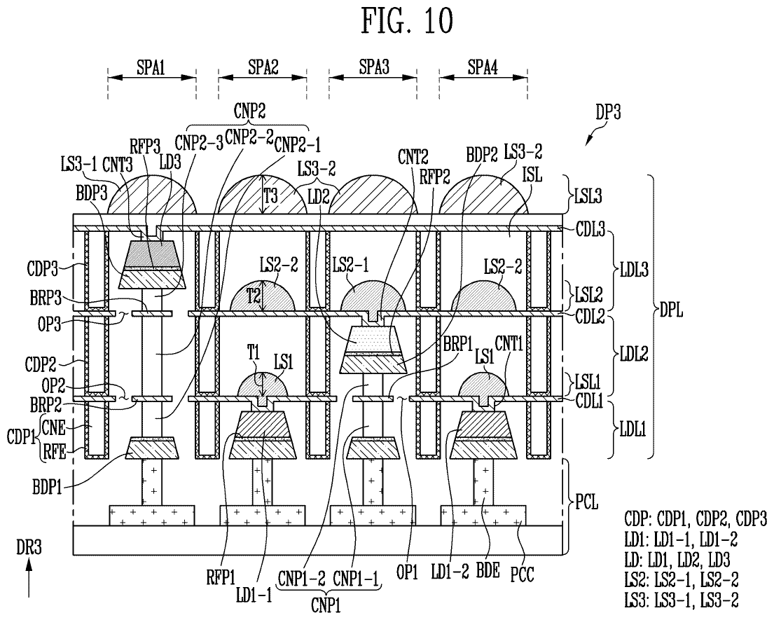

In an embodiment and referring to FIG. 10, in a display panel DP3, at least some of lenses included in the lens layers LSL1, LSL2, and LSL3 may have the same shape of a spherical surface as the others of the lenses included in the lens layers LSL1, LSL2, and LSL3, and have a height different from a height of the others of the lenses included in the lens layers LSL1, LSL2, and LSL3.

For example, in an embodiment, first lenses LS1 included in the first lens layer LSL1 may have the same shape, second lenses LS2 included in the second lens layer LSL2 may have the same shape, and third lenses LS3 included in the third lens layer LSL3 may have the same shape.

However, in an embodiment, since the first lenses LS1, the second lenses LS2, and the third lenses LS3 have different distances between light emitting elements LD and the lenses and different distances between the top surface of the display element layer DPL and the lenses as conditions which have influence on a path of light generated by each light emitting element LD, and are formed through different processes, the first lenses LS1, the second lenses LS2, and the third lenses LS3 may have different shapes.

That is, the first lenses LS1 may have a shape different from shapes of the second lenses LS2 and the third lenses LS3, and the second lenses LS2 may have a shape different from a shape of the third lenses LS3.

For example, in an embodiment, the lenses LS1 to LS3 may have different curvatures, different curvature radii, different shapes of spherical surfaces, different heights, and different widths.

In an embodiment, shapes of spherical surfaces of the lenses LS1 to LS3 may be the same. For example, the shape of the spherical surface of each of the lenses LS1 to LS3 may be a hemispherical shape. However, embodiments of the present disclosure are not limited thereto.

In an embodiment, the first lenses LS1, the second lenses LS2, and the third lenses LS3 may have different sizes. That is, the first lenses LS1, the second lenses LS2, and the third lenses LS3 may have different heights and different widths.

In an embodiment, each of the first lenses LS1 may have a first height T1 and a first width. Each of the second lenses LS2 may have a second height T2 and a second width. Each of the third lenses LS3 may have a third height T3 and a third width. A size of each of the first lenses LS1 may be smallest, and a size of each of the third lenses LS3 may be greatest. That is, the first height T1 and the first width may be smallest, and the third height T3 and the third width may be greatest. Accordingly, since the size of each of the first lenses LS1 is smallest, the optical path of the first light emitting element LD1 may be reduced. Since the optical path of the first light emitting element LD1 is reduced, the light emission efficiency of the first light emitting element LD1 may be improved. Like the first lenses LS1, the second lenses LS2 may reduce the optical path of the second light emitting element LD2, thereby improving the light emission efficiency of the second light emitting element LD2.

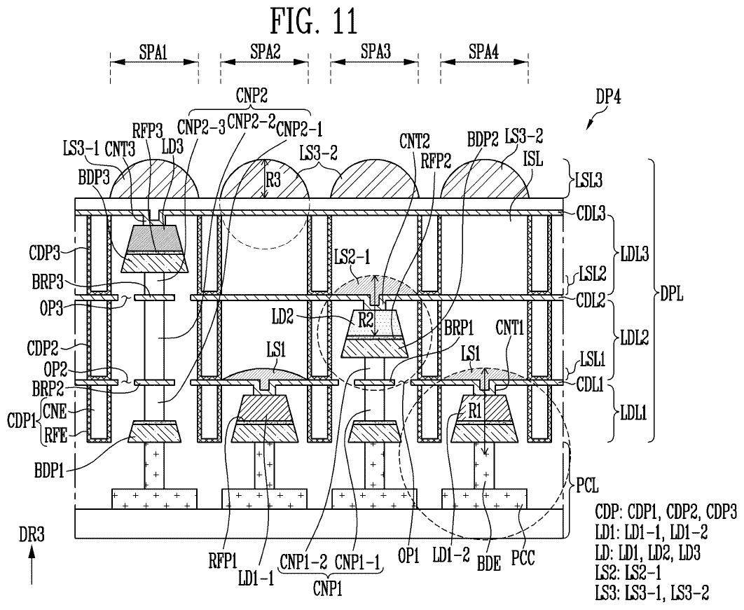

In a display panel DP4, in accordance with an embodiment shown in FIG. 11, unlike the embodiment shown in FIG. 9, the second lens layer LSL2 includes only the (2-1)th lens LS2-1, and does not include the (2-2)th lenses LS2-2 overlapping with the first light emitting element LD1. That is, as compared with FIG. 9, the number of lenses overlapping with the first light emitting element LD1 may be decreased from three to two.

In an embodiment and referring to FIG. 11, at least some of lenses included in the lens layers LSL1, LSL2, and LSL3 may have a curvature different from a curvature of the others of the lenses included in the lens layers LSL1, LSL2, and LSL3, and have a shape of a spherical surface, which is different from a shape of a spherical surface of the others of the lenses included in the lens layers LSL1, LSL2, and LSL3.

In an embodiment, since first lenses LS1, second lenses LS2, and third lenses LS3 have different distances between light emitting elements LD and the lenses and different distances between the top surface of the display element layer DPL and the lenses as conditions which have influence on a path of light generated by each light emitting element LD, and are formed through different processes, the first lenses LS1, the second lenses LS2, and the third lenses LS3 may have different shapes.

For example, the lenses LS1 to LS3 may have different curvatures, different curvature radii, different shapes of spherical surfaces, and different heights.

In an embodiment, a curvature of each of the first lenses LS1 may be smaller than a curvature of each of the second lenses LS2 and the third lenses LS3. That is, a curvature radius R1 of each of the first lenses LS1 may be greater than a curvature radius R2 of each of the second lenses LS2 and a curvature radius R3 of each of the third lenses LS3. In addition, a curvature of each of the second lenses LS2 may be smaller than a curvature of each of the third lenses LS3. That is, the curvature radius R2 of each of the second lenses LS2 may be greater than the curvature radius R3 of each of the third lenses LS3.

In an embodiment, the curvature of each of the first lenses LS1 located above the first light emitting element LD1 located lowermost may be smallest, and the curvature radium R1 of each of the first lenses LS1 may be greatest. Accordingly, the first lenses LS1 among the lenses LS1 to LS3 may send incident light farthest. Since the first lenses LS1 located above the first light emitting element LD1 send light emitted from the first light emitting element LD1 farthest, and the (3-2)th lenses LS3-2 located above the first light emitting element LD1 condense lights passing through the first lenses LS1, the (2-2)th lenses LS2-2 located between the first lenses LS1 and the (3-2)th lens LS3-2 may be omitted. Accordingly, the structure of the display panel DP4 can be simplified, and the efficiency of processes can be improved.

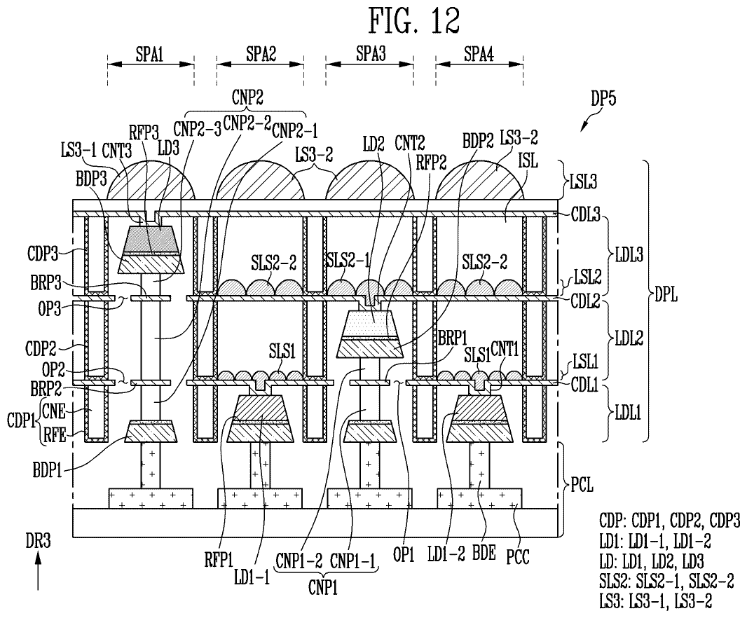

In a display panel DP5, in accordance with an embodiment shown in FIG. 12, unlike the embodiment shown in FIG. 9, each of the first lens layer LSL1 and the second lens layer LSL2 may include a plurality of sub-lenses overlapping with one sub-pixel area.

In an embodiment and referring to FIG. 12, each of the first lens layer LSL1 and the second lens layer LSL2 may further include a plurality of sub-lenses.

In an embodiment, the first lens layer LSL1 may include first sub-lenses SLS1 overlapping with each of the (1-1)th light emitting element LD1-1 and the (1-2)th light emitting element LD1-2. The second lens layer LSL2 may further include (2-1)th sub-lenses SLS2-1 overlapping with the second light emitting element LD2 and (2-2)th sub-lenses SLS2-2 overlapping with each of the (1-1)th light emitting element LD1-1 and the (1-2)th light emitting element LD1-2.

In an embodiment, the first sub-lenses SLS1 included in the first lens layer LSL1 may have the same shape, the second sub-lenses SLS2 included in the second lens layer LSL2 may have the same shape, and the third lenses LS3 included in the third lens layer LSL3 may have the same shape. In addition, the first sub-lenses SLS1 may have a shape different from shapes of the second sub-lenses SLS2 and the third lenses LS3, and the second sub-lenses LSL2 may have a shape different from a shape of the third lenses LS3.

In an embodiment, a plurality of first sub-lenses SLS1 are to be located in one sub-pixel area, and therefore, a size of the plurality of first sub-lenses SLS1 may be smaller than a size of each of the third lens LS3. That is, a height and a width of each of the plurality of first sub-lenses SLS1 may be smaller than a height and a width of each of the third lenses LS3. However, the invention is not limited thereto. In another embodiment, the height of each of the plurality of first sub-lenses SLS1 may be equal to the height of each of the third lenses LS3, and only the width of each of the plurality of first sub-lenses SLS1 may be smaller than the width of each of the third lenses LS3. Each of the plurality of first sub-lenses SLS1 may be formed in a shape in which a hemisphere is located on a circular pillar.

In an embodiment, like the plurality of first sub-lenses SLS1, a plurality of second sub-lenses SLS2 are also to be located in one sub-pixel area, and therefore, a size of each of the plurality of second sub-lenses SLS2 may be smaller than the size of each of the third lenses LS3.

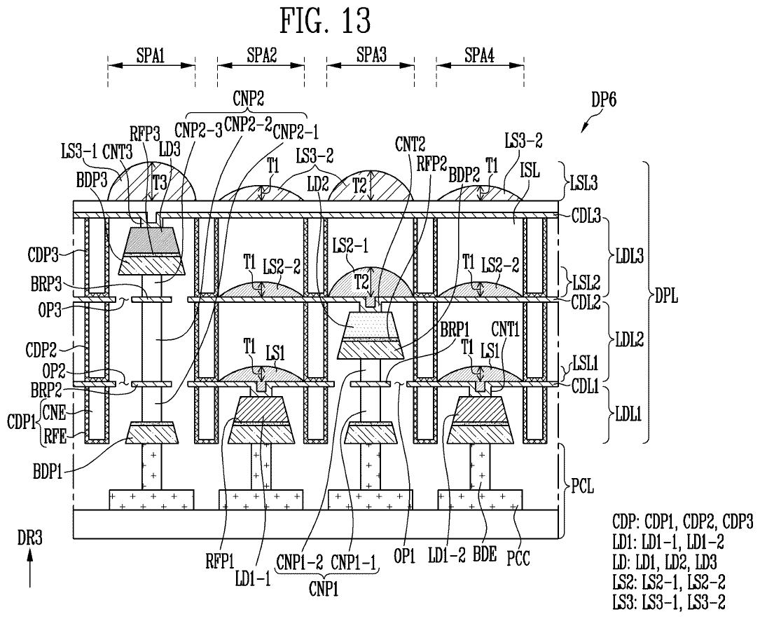

In a display panel DP6, in accordance with an embodiment shown in FIG. 13, unlike the embodiment shown in FIG. 9, second lenses LS2 included in the second lens layer LSL2 may have different shapes, and third lenses LS3 included in the third lens layer LSL3 may have different shapes.

In an embodiment and referring to FIG. 13, lenses included in each of the lens layers LSL1, LSL2, and LSL3 may have different shapes.

In an embodiment, some of second lenses LS2 may have a shape different from a shape of the other lenses among the second lenses LS2, and some of third lenses LS3 may have a shape different from a shape of the other lenses among the third lenses LS3.

Specifically, in an embodiment, since first lenses LS1 included in the first lens layer LSL1 have the same conditions such as a distance from the first light emitting element LD and a distance up to the top surface of the display element layer DPL, the first lenses LS1 may have the same shape.

Similarly, in an embodiment, since (2-2)th lenses LS2-2 included in the second lens layer LSL2 may also have the same conditions such as a distance from the first light emitting element LD and a distance up to the top surface of the display element layer DPL, the (2-2)th lenses LS2-2 may have the same shape.

In an embodiment, a (2-1)th lens LS2-1 and the (2-2)th lenses LS2-2 may have the same distance up to the top surface of the display element layer DPL, but have different distances from light emitting elements LD disposed thereunder and different characteristics of the light emitting elements LD. Therefore, the (2-1)th lens LS2-1 and the (2-2)th lenses LS2-2 may have different shapes.

Similarly, in an embodiment, since (3-2)th lenses LS3-2 overlapping with the second sub-pixel area SPA2 and the fourth sub-pixel area SPA4, which are included in the third lens layer LSL3, may also have the same conditions such as a distance from the first light emitting element LD and a distance up to the top surface of the display element layer DPL, the (3-2)th lenses LS3-2 may have the same shape.

In an embodiment, a (3-1)th lens LS3-1, a (3-2)th lens LS3-2 overlapping with the third sub-pixel area SPA3, and the (3-2)th lenses LS3-2 overlapping with the second sub-pixel area SPA2 and the fourth sub-pixel area SPA4 may have the same distance up to the top surface of the display element layer DPL, but have different distances from light emitting elements LD disposed thereunder and different characteristics of the light emitting elements LD. Therefore, the 3-1)th lens LS3-1, the (3-2)th lens LS3-2, and the (3-2)th lenses LS3-2 may have different shapes.

In an embodiment, as the lenses included in each of the lens layers LSL1 to LSL3 have different shapes, the lenses may be formed using a halftone mask when the lens layers LSL1 to LSL3 are formed. Accordingly, even lenses located in the same layer may have different shapes, and therefore, a lens structure for an optimum optical path of each light emitting element LD may be formed.

In an embodiment, lenses overlapping with each other on a plane may have the same shape. That is, lenses overlapping with each other for each sub-pixel area may have the same height and the same width. The first lenses LS1 overlapping with the first light emitting element LD1, the (2-2)the lenses LS2-2, and the (3-2)th lenses LS3-2 overlapping with the sub-pixel areas SPA2 and SPA4 among the third lenses LS3 may have the same shape. The (2-1)th lens LS2-1 overlapping with the second light emitting element LD2 and the (3-2)th lens overlapping with the third sub-pixel area SPA3 among the third lenses LS3 may have the same shape.

That is, lenses which have influence on an optical path of the same light emitting element LD may have the same shape.

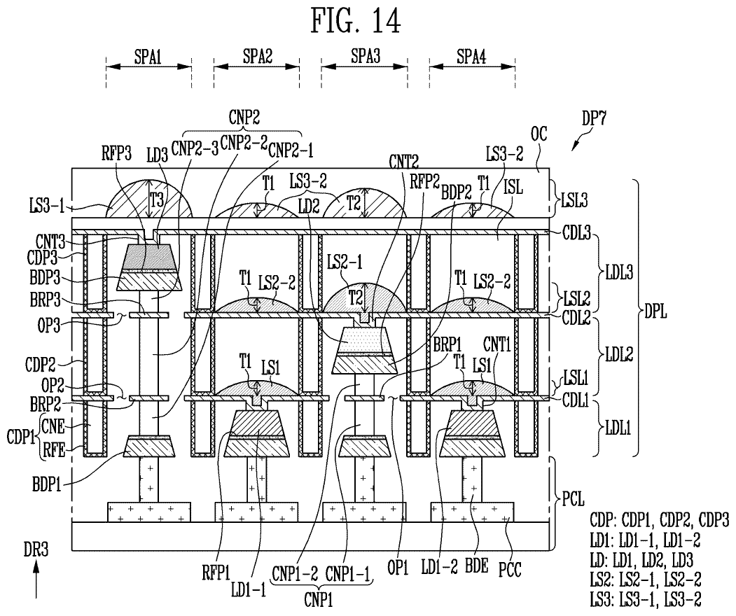

A display panel DP7, in accordance with an embodiment shown in FIG. 14 may include an overcoat layer OC disposed on the third lens layer LSL3, unlike the embodiment shown in FIG. 13.

In an embodiment and referring to FIG. 14, the display panel DP7 may further include the overcoat layer OC.

In an embodiment, the overcoat layer OC may be disposed over the third light emitting element layer LDL3 and the third lens layer LSL3 and cover the third lenses LS3 included in the third lens layer LSL3. That is, the overcoat layer OC may cover the third lenses LS3, planarize the top surface of the display element layer DPL and protect the third lenses LS3.

In an embodiment, the overcoat layer OC may include an organic material. A refractive index of the material constituting the overcoat layer OC may be smaller than the refractive index of a material constituting the third lens layer LSL3.

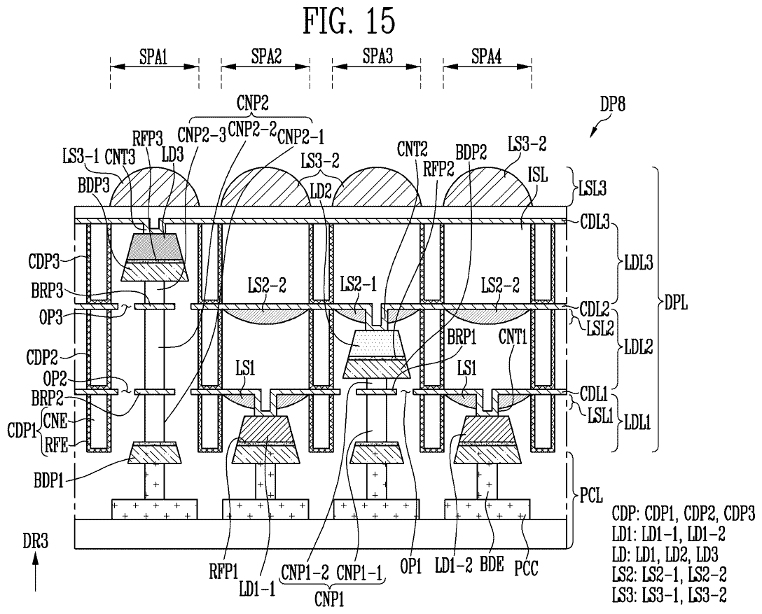

A display panel DP8, in accordance with an embodiment shown in FIG. 15 may include concave lenses formed by the first lens layer LSL1 and the second lens layer LSL2, unlike the embodiment shown in FIG. 9.

In an embodiment and referring to FIG. 15, at least some of lenses included in the lens layers LSL1, LSL2, and LSL3 may have a shape convex toward the pixel circuit layer PCL, and the others of the lenses included in the lens layers LSL1, LSL2, and LSL3 may have a shape convex toward the third direction DR3 as a direction opposite to the pixel circuit layer PCL.

In an embodiment, each of first lenses LS1 included in the first lens layer LSL1 may have a shape convex toward the pixel circuit layer PCL. Similarly, each of second lenses LS2 included in the second lens layer LSL2 may have a shape convex toward the pixel circuit layer PCL. Each of third lenses LS3 included in the third lens layer LSL3 may have a shape convex toward the third direction DR3. However, the invention is not limited thereto.

In an embodiment, each of the light emitting element layers LDL1, LDL2, and LDL3 may further include an insulating layer ISL. The insulating layer ISL may be disposed adjacent to the lens layers LSL1, LSL2, and LSL3, and may be in contact with at least one surface of each of the lens layers LSL1, LSL2, and LSL3. For example, the insulating layer ISL may be in contact with a spherical surface of each of the lenses included in the lens layers LSL1 and LSL2.

In an embodiment, a refractive index of a material constituting each of the first lenses LS1 and the second lenses LS2, which has a shape convex toward the pixel circuit layer PCL, may be lower than a refractive index of a material constituting the insulating layer ISL. Accordingly, each of the first lenses LS1 and the second lenses LS2 does not serve as a convex lens, but the insulating layer ISL in contact with the first lenses LS1 and the second lenses LS2 may serve as a concave lens.

Therefore, in an embodiment, the display panel DP8 may include not only convex lenses (e.g., the third lenses LS3) but also concave lenses (e.g., the first and second lenses LS1 and LS2), thereby having a combination of the convex and concave lenses.

In a display panel DP9, in accordance with an embodiment shown in FIG. 16, unlike the embodiment shown in FIG. 9, the conductive patterns CDP may be partially omitted.

In an embodiment and referring to FIG. 16, the first light emitting element layer LDL1 may include only first conductive patterns CDP1 surrounding the first light emitting element LD1. That is, the first conductive patterns CDP1 may be disposed while surrounding only each of the second sub-pixel area SPA2 and the fourth sub-pixel area SPA4.

In an embodiment, the second light emitting element layer LDL2 may include only second conductive patterns CDP2 surrounding the second light emitting element LD2. That is, the second conductive patterns CDP2 may be disposed while surrounding only the third sub-pixel area SPA3.

In an embodiment, the third light emitting element layer LDL3 may include only third conductive patterns CDP3 surrounding the third light emitting element LD3. That is, the third conductive patterns CDP3 may be disposed while surrounding only the first sub-pixel area SPA1.

In an embodiment, as the lens layers LSL1, LSL2, and LSL3 are disposed between the light emitting element layers LDL1, LDL2, and LDL3, respectively, the light emission efficiency of the light emitting element LD may be improved by the lens layers LSL1, LSL2, and LSL3. Thus, although the conductive patterns CDP for improving the light emission efficiency are partially omitted, this does not have great influence on the luminance of the display panel DP9.

In addition, in an embodiment, as the conductive patterns CDP are partially omitted, the opening ratio of each sub-pixel may be increased. Thus, the luminance of the display panel DP9 can be additionally improved as the opening ratio of the sub-pixel is increased.

In a display panel DP10, in accordance with an embodiment shown in FIG. 17, unlike the embodiment shown in FIG. 16, the conductive patterns CDP may all be omitted.

In an embodiment and referring to FIG. 17, each of the light emitting element layers LDL1, LDL2, and LDL3 may not include the conductive patterns CDP.

In an embodiment, as the lens layers LSL1, LSL2, and LSL3 are disposed between the light emitting element layers LDL1, LDL2, and LDL3, respectively, the light emission efficiency of the light emitting element LD may be improved by the lens layers LSL1, LSL2, and LSL3. Thus, although the conductive patterns CDP for improving the light emission efficiency are all omitted, this does not have great influence on the luminance of the display panel DP10.

In addition, in an embodiment, as the conductive patterns CDP are all omitted, the opening ratio of each sub-pixel may be maximized. Thus, the luminance of the display panel DP10 can be additionally improved as the opening ratio of the sub-pixel is maximized.

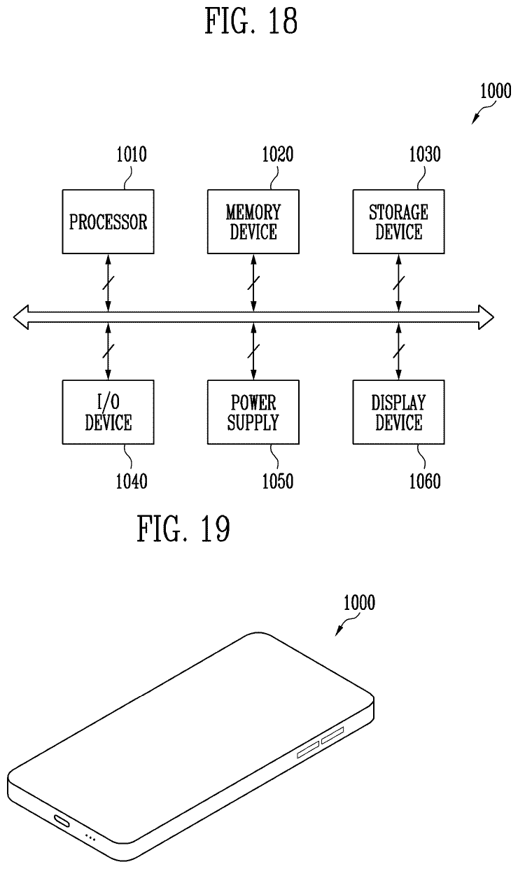

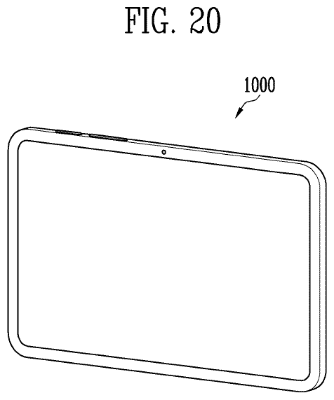

FIG. 18 is a schematic block diagram illustrating an electronic device 1000 including a display device, in accordance with an embodiment. FIG. 19 is a graphical image illustrating an example where the electronic device 1000 of FIG. 18 is a smartphone. FIG. 20 is a graphical image illustrating an example where the electronic device 1000 of FIG. 18 is a tablet computer.

In an embodiment and referring to FIGS. 18 to 20, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 19, the electronic device 1000 may be a smartphone. In an embodiment, as illustrated in FIG. 20, the electronic device 1000 may be a tablet computer. However, the aforementioned examples are illustrative, and the electronic device 1000 is not necessarily limited to the aforementioned examples. For example, in other embodiments, the electronic device 1000 may be a cellular phone, a video phone, a smart pad, a smartwatch, a navigation device for vehicles, a computer monitor, a laptop computer, a head-mounted display device, or the like.

In an embodiment, the processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data to the display device 1060.

In an embodiment, the memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

In an embodiment, the storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

In an embodiment, the I/O device 1040 may include input devices such as a keyboard, a keypad, a touchpad, a touch screen, and a mouse, and output devices such as a speaker and a printer. In an embodiment, the display device 1060 may be integrated with the I/O device 1040.

In an embodiment, the power supply 1050 may supply power needed to perform the operation of the electronic device 1000. For example, the power supply 1050 may include a power management integrated circuit (PMIC). In an embodiment, the power supply 1050 may supply power to the display device 1060.

In an embodiment, the display device 1060 may display images in response to image data signals and/or control signals from the processor 1010. The display device 1060 may be connected to other components through the buses or other communication links.

In accordance with the invention, the display device further includes first to third lens layers disposed between first to third light emitting element layers and on the third light emitting element layer, so that a focal distance as a distance between each of the first to third light emitting elements in all light emitting elements and each of lenses can be decreased. That is, a distance between a light emitting element in all the light emitting elements and a lens overlapping with the light emitting element can be minimized. Thus, a difference between optical paths of the first to third light emitting elements, which caused due to a stacked structure of the first to third light emitting elements, can be compensated through the lenses included in the first to third lenses. Accordingly, the light emission efficiency of the display panel can be maximized.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention.

What is claimed is:

1. A display device comprising:
a pixel circuit layer including a pixel circuit;
a first light emitting element layer disposed on the pixel circuit layer, the first light emitting element layer including a first light emitting element generating light of a first color;
a second light emitting element layer disposed on the first light emitting element layer, the second light emitting element layer including a second light emitting element which generates light of a second color different from the first color and which is spaced apart from the first light emitting element on a plane;
a third light emitting element layer disposed on the second light emitting element layer, the third light emitting element layer including a third light emitting element which generates light of a third color different from the first color and the second color and which is spaced apart from the first light emitting element and the second light emitting element on the plane;
a first lens layer disposed between the first light emitting element layer and the second light emitting element layer, the first lens layer including a lens overlapping with the first light emitting element;
a second lens layer disposed between the second light emitting element layer and the third light emitting element layer, the second lens layer including a lens overlapping with the second light emitting element; and
a third lens layer disposed on the third light emitting element layer, the third lens layer including lenses respectively overlapping with the first to third light emitting elements.

2. The display device of claim 1, wherein at least some of the lenses included in the first to third lens layers have a shape different from a shape of others of the lenses included in the first to third lens layers.

3. The display device of claim 1, wherein at least some of the lenses included in the first to third lens layers have a curvature different from a curvature of others of the lenses included in the first to third lens layers.

4. The display device of claim 1, wherein a shape of a spherical surface of each of at least some of the lenses included in the first to third lens layers is different from a shape of a spherical surface of each of others of the lenses included in the first to third lens layers.

5. The display device of claim 1, wherein at least some of the lenses included in the first to third lens layers have a same shape of a spherical surface as others of the lenses included in the first to third lens layers, and have a height which is different from a height of the others of the lenses included in the first to third lens layers.

6. The display device of claim 1, wherein the first light emitting element layer includes a (1-1)th light emitting element and a (1-2)th light emitting element, which are spaced apart from the second light emitting element and the third light emitting element on the plane.

7. The display device of claim 6, wherein the first lens layer includes first lenses respectively overlapping with the (1-1)th light emitting element and the (1-2)th light emitting element.

8. The display device of claim 7, wherein the second lens layer further includes:
a (2-1)th lens overlapping with the second light emitting element; and
(2-2)th lenses respectively overlapping with the (1-1)th light emitting element and the (1-2)th light emitting element.

9. The display device of claim 8, wherein one or more lenses included in the first lens layer have a same shape,
wherein one or more lenses included in the second lens layer have a same shape, and
wherein one or more lenses included in the third lens layer have a same shape.

10. The display device of claim 9, wherein the lenses included in the first lens layer have a shape different from a shape of the lenses included in each of the second lens layer and the third lens layer, and
wherein the lenses included in the second lens layer have a shape different from a shape of the lenses included in the third lens layer.

11. The display device of claim 8, wherein some of the lenses included in the second lens layer have a shape different from a shape of others of the lenses included in the second lens layer, and
wherein some of the lenses included in the third lens layer have a shape different from a shape of others of the lenses included in the third lens layer.

12. The display device of claim 11, wherein lenses overlapping with each other on a plane among the lenses included in the first to third lens layers have the same shape.

13. The display device of claim 6, wherein the first lens layer includes first sub-lenses overlapping with each of the (1-1)th light emitting element and the (1-2)th light emitting element.

14. The display device of claim 13, wherein the second lens layer includes:
(2-1)th sub-lenses overlapping with the second light emitting element; and
(2-2)th sub-lenses overlapping with each of the (1-1)th light emitting element and the (1-2)th light emitting element.

15. The display device of claim 2, wherein at least some of the lenses included in the first to third lens layers have a shape convex toward the pixel circuit layer, and others of the lenses included in the first to third lens layers have a shape convex toward a direction opposite to the pixel circuit layer.

16. The display device of claim 15, wherein each of the first to third light emitting element layers further includes an insulating layer, and
wherein a refractive index of a material constituting each of the lenses having the shape convex toward the pixel circuit layer is lower than a refractive index of a material constituting the insulating layer.

17. The display device of claim 1, wherein each of the first to third light emitting element layers further includes conductive patterns surrounding the first to third light emitting elements without overlapping with the first to third light emitting elements on a plane.

18. The display device of claim 1, wherein the first lens layer and the second lens layer include the same material, and
wherein the first and second lens layers and the third lens layer have different materials.

19. The display device of claim 18, wherein the first lens layer and the second lens layer include an inorganic material, and
the third lens layer includes an organic material.

20. An electronic device, comprising:
a processor to provide input image data; and
a display device to display an image based on the input image data,
wherein the display device comprises: a pixel circuit layer including a pixel circuit;
a first light emitting element layer disposed on the pixel circuit layer, the first light emitting element layer including a first light emitting element generating light of a first color;
a second light emitting element layer disposed on the first light emitting element layer, the second light emitting element layer including a second light emitting element which generates light of a second color different from the first color and which is spaced apart from the first light emitting element on a plane;
a third light emitting element layer disposed on the second light emitting element layer, the third light emitting element layer including a third light emitting element which generates light of a third color different from the first color and the second color and which is spaced apart from the first light emitting element and the second light emitting element on the plane;
a first lens layer disposed between the first light emitting element layer and the second light emitting element layer, the first lens layer including a lens overlapping with the first light emitting element;
a second lens layer disposed between the second light emitting element layer and the third light emitting element layer, the second lens layer including a lens overlapping with the second light emitting element; and
a third lens layer disposed on the third light emitting element layer, the third lens layer including lenses respectively overlapping with the first to third light emitting elements.
